(19) United States
(12) Patent Application Publication
(10) Pub. No.: US 2024/0385485 A1
(43) Pub. Date: Nov. 21, 2024

(54) DISPLAY PANEL AND DISPLAYING DEVICE

(71) Applicants: Hefei BOE Display Technology Co., Ltd., Hefei, Anhui (CN); BOE Technology Group Co., Ltd., Beijing (CN)

(72) Inventors: Chunxu Zhang, Beijing (CN); Maoxiu Zhou, Beijing (CN); Xiaoting Jiang, Beijing (CN); Min Cheng, Beijing (CN); Haipeng Yang, Beijing (CN); Ke Dai, Beijing (CN); Hui Li, Beijing (CN)

(73) Assignees: Hefei BOE Display Technology Co., Ltd., Hefei, Anhui (CN); BOE Technology Group Co., Ltd., Beijing (CN)

(21) Appl. No.: 18/272,118

(22) PCT Filed: Sep. 29, 2022
(86) PCT No.: PCT/CN2022/122820

§ 371 Date: Jul. 13, 2023

(51) Int. Cl. G02F 1/1362; G02F 1/1343; G02F 1/1368; H01L 27/12

(52) U.S. Cl. CPC G02F 1/136286; G02F 1/134345; G02F 1/1368; H01L 27/124

(57) ABSTRACT

A display panel includes: a first active area and at least one second active area, a substrate; a plurality of sub-pixels located on the substrate, the plurality of sub-pixels being in the first active area, and each of the sub-pixels including a common electrode; grid lines and data lines, at least one of the data lines being located at a junction of the first active area and the second active area; a plurality of first conductive patterns at least in the second active area, and the first conductive patterns being electrically connected to one of the grid lines or the common electrode; and a plurality of second conductive patterns in the second active area and electrically connected to the data line at the junction, orthographic projections of part first conductive patterns on the substrate overlap orthographic projections of the second conductive patterns on the substrate.

### TECHNICAL FIELD

The present application relates to the technical field of displaying, and particularly relates to a display panel and a displaying device.

### BACKGROUND

For Z-Inversion technology display products, in order to achieve an extremely narrow border effect, the Dummy sub-pixels arranged close to the surrounding area in the active area will be removed. In this way, compared with other data lines in the active area, on the data lines close to the surrounding area in the active area, only half of the connected transistors are provided with pixel electrodes and common electrodes at one side, this leads to a large capacitive load difference between this data line and other data lines in the active area, resulting in a significant difference in charging rate between the data line and other data lines, seriously reducing the display effect.

### SUMMARY

The embodiments of the present application employ the following technical solutions:

In the first aspect, an embodiment of the present application provides a display panel, the display panel includes a first active area and at least one second active area, the second active area is located at one side of the first active area, and the display panel further includes:

a substrate:

a plurality of sub-pixels located on the substrate and arranged in array, wherein the plurality of sub-pixels are located in the first active area, and each of the plurality of sub-pixels comprises a common electrode:

a plurality of grid lines and a plurality of data lines that are located on the substrate, wherein the plurality of grid lines and the plurality of data lines are intersecting and insulated, the plurality of sub-pixels are located at a position defined by the plurality of grid lines and the plurality of data lines, at least one of the data lines is located at a junction of the first active area and the second active area:

a plurality of first conductive patterns, wherein the first conductive patterns are at least located in the second active area, and the first conductive patterns are electrically connected to one of the grid lines or the common electrode: and

a plurality of second conductive patterns located in the second active area and electrically connected to the at least one of the data lines located at the junction: wherein orthographic projections of part of the first conductive patterns on the substrate overlap with orthographic projections of the second conductive patterns on the substrate.

In the display panel according to an embodiment of the present application, the plurality of first conductive patterns comprise a first part:

the first conductive patterns of the first part are located in the second active area and are electrically connected to the grid lines: and the orthographic projections of the second conductive patterns on the substrate are located within orthographic projections of the first conductive patterns of the first part on the substrate.

In the display panel according to an embodiment of the present application, the plurality of first conductive patterns comprise a second part;

the first conductive patterns of the second part extend from the first active area to the second active area, and are electrically connected to the common electrode: orthographic projections of the first conductive patterns of the second part on the substrate overlap with an orthographic projection of the data line located at the junction on the substrate.

In the display panel according to an embodiment of the present application, outer contours of the orthographic projections of the second conductive patterns on the substrate are located within outer contours of the orthographic projections of the first conductive patterns of the first part on the substrate.

In the display panel according to an embodiment of the present application, the second active area comprises a plurality of first dummy capacitances, the first conductive patterns of the first part are regarded as first electrodes of the first dummy capacitances, and the second conductive patterns are regarded as second electrodes of the first dummy capacitances.

In the display panel according to an embodiment of the present application, the second active area comprises a plurality of dummy transistors, gates of the dummy transistors are electrically connected to the grid lines, first ends of the dummy transistors are electrically connected to the data line located at the junction, and second ends of the dummy transistors are arranged in isolation.

In the display panel according to an embodiment of the present application, part regions of the first conductive patterns of the first part are regarded as the gates of the dummy transistors:

at least part of the second conductive patterns comprises first conductive parts and second conductive parts, the first conductive parts are disconnected from the second conductive parts, the first conductive parts are regarded as the first ends of the dummy transistors, and the second conductive parts are regarded as the second ends of the dummy transistors.

In the display panel according to an embodiment of the present application, a quantity of the dummy transistors is less than or equal to half a quantity of rows of the sub-pixels.

In the display panel according to an embodiment of the present application, each of the grid lines divides the data line located at the junction into a plurality of data line segments: the first active area comprises a plurality of transistors, part of the data line segments is electrically connected to the transistors, at least part of the data line segments that are not connected to the transistors is electrically connected to the dummy transistors.

In the display panel according to an embodiment of the present application, the quantity of the dummy transistors is equal to half the quantity of rows of the sub-pixels, the data line segments that are not connected to the transistors are electrically connected to the dummy transistors, and the data line segments electrically connected to the transistors and the data line segments electrically connected to the dummy transistors are arranged at intervals.

In the display panel according to an embodiment of the present application, the first conductive patterns of the second part and the common electrode are an integrated structure.

In the display panel according to an embodiment of the present application, the display panel comprises a plurality of second dummy capacitances, the first conductive patterns of the second part are regarded as first electrodes of the second dummy capacitances, part line segments of the data line located at the junction are regarded as second electrodes of the second dummy capacitances;

wherein an area of an orthographic projection of a part of the first conductive patterns of the second part that is located in the second active area on the substrate is greater than an area of an orthographic projection of a part of the first conductive patterns of the second part that is located in the first active area on the substrate.

In the display panel according to an embodiment of the present application, graphics of the orthographic projections of the first conductive patterns of the second part on the substrate comprise polygons, arcs, or combinations of the polygons and the arcs.

In the display panel according to an embodiment of the present application, graphics of the orthographic projections of the first conductive patterns of the second part on the substrate comprise a first side and a second side that face each other, extension directions of the first side and the second side are the same, the first side is located in the second active area, the second side is located in the first active area, a length of the first side along the extension direction of the first side is greater than or equal to a length of the second side along the extension direction of the second side.

In the display panel according to an embodiment of the present application, in a direction perpendicular to a plane where the substrate is located, a distance from the first conductive patterns of the second part to the data line located at the junction is a first distance; and

the graphics of the orthographic projections of the first conductive patterns of the second part on the substrate comprise a right trapezoid, and a difference of sizes of an upper bottom and a lower bottom of the right trapezoid is proportional to the first distance.

In the display panel according to an embodiment of the present application, in a direction perpendicular to a plane where the substrate is located, a distance from the first conductive patterns of the second part to the data line located at the junction is a first distance; and

the graphics of the orthographic projections of the first conductive patterns of the second part on the substrate comprise a combination of a rectangle and a first graphic, the first graphic comprises a plurality of right trapezoids, a right-angle side of each of the plurality of right trapezoids is in contact with the rectangle, and a sum of sizes of an upper bottom and a lower bottom of each of the plurality of right trapezoids is proportional to the first distance.

In the display panel according to an embodiment of the present application, graphics of the orthographic projections of the first conductive patterns of the second part on the substrate comprise a combination of a second graphic and a third graphic that are connected, the second graphic comprises a chamfered rectangle, and the third graphic comprises a polygon, an arc, or a combination of the polygon and the arc;

wherein the second graphic extends from the first active area to the second active area, the third graphic is located in the second active area, a part of the first conductive patterns of the second part whose orthographic projection is the third graphic is in directly contact with a common electrode line of the display panel, and a chamfer of the chamfered rectangle is located in the second active area.

In the display panel according to an embodiment of the present application, vertex angles of graphics of the orthographic projections of the first conductive patterns of the second part on the substrate include a round corner.

In the display panel according to an embodiment of the present application, a quantity of the second dummy capacitance is greater than or equal to half a quantity of rows of the sub-pixels.

In the display panel according to an embodiment of the present application, each of the grid lines divides the data line located at the junction into a plurality of data line segments; orthographic projections of at least part of the data line segments on the substrate overlap with the orthographic projections of the first conductive patterns of the second part on the substrate.

In the display panel according to an embodiment of the present application, the quantity of the second dummy capacitance is equal to the quantity of rows of the sub-pixels, the orthographic projections of the data line segments on the substrate overlap with the orthographic projections of the first conductive patterns of the second part on the substrate.

In the display panel according to an embodiment of the present application, the quantity of the second dummy capacitance is equal to half the quantity of rows of the sub-pixels, orthographic projections of half of the data line segments on the substrate overlap with the orthographic projections of the first conductive patterns of the second part on the substrate.

In the display panel according to an embodiment of the present application, each of the data line segments comprises a first group and a second group, orthographic projections of data line segments of the first group on the substrate overlap with the orthographic projections of the first conductive patterns of the second part on the substrate, orthographic projections of data line segments of the second group on the substrate do not overlap with the orthographic projections of the first conductive patterns of the second part on the substrate; wherein the data line segments of the first group and the data line segments of the second group are arranged at intervals.

In the display panel according to an embodiment of the present application, a capacitive load difference exists between the data line located at the junction and the data lines in the first active area, one of the second dummy capacitances is configured to be capable of compensating for the capacitive load difference between two data line segments.

In the display panel according to an embodiment of the present application, the display panel further comprises a third conductive pattern, the third conductive pattern is electrically connected to the common electrode, the third conductive pattern is at least located in the second active area, and at least part region of the third conductive pattern is located between the first conductive patterns of the first part and the data line located at the junction;

wherein an orthographic projection of the at least part region of the third conductive pattern on the substrate do not overlap with the orthographic projection of the data line located at the junction on the substrate.

In the display panel according to an embodiment of the present application, the display panel further comprises a third dummy capacitance, the third conductive pattern is regarded as a first electrode of the third dummy capacitance and is electrically connected to the common electrode, part line segments of the data line located at the junction are regarded as a second electrode of the third dummy capacitance.

In the display panel according to an embodiment of the present application, an orthographic projection of the third conductive pattern on the substrate do not overlap with the orthographic projection of the data line located at the junction on the substrate.

In the display panel according to an embodiment of the present application, the sub-pixels in a same row are connected to the same grid line;

a column of the sub-pixels are provided between every two adjacent data lines, the sub-pixels in a same column comprises a first category and a second category, any one of the sub-pixels of the first category is located between two sub-pixels of the second category, wherein the first category of the sub-pixels in the same column is electrically connected to one data line, the second category of the sub-pixels in the same column is electrically connected to another data line.

In the display panel according to an embodiment of the present application, the plurality of grid lines divide the data lines in the first active area into a plurality of data line segment, in the plurality of data line segments, part of the data line segments comprise support parts, first connecting parts and second connecting parts, the support parts are located between the first connecting parts and the second connecting parts;

wherein a size of each of the support parts in a direction perpendicular to an extension direction of the data line segment is greater than a size of each of the first connecting parts in the direction perpendicular to the extension direction of the data line segment, and the size of each of the support parts in the direction perpendicular to the extension direction of the data line segment is greater than a size of each of the second connecting part in the direction perpendicular to the extension direction of the data line segment.

In the display panel according to an embodiment of the present application, the display panel further comprises spacers and protection parts, the spacers are located at sides of part of the support parts away from the substrate, the protection parts are located at at least one side of each of the support parts; and heights of the protection parts in a direction perpendicular to a plane where the substrate is located is greater than heights of the support parts in the direction perpendicular to the plane where the substrate is located.

In a second aspect, the present application provides a displaying device, including the display panel according to the first aspect.

The above description is merely a summary of the technical solutions of the present application. In order to more clearly know the elements of the present application to enable the implementation according to the contents of the description, and in order to make the above and other purposes, features and advantages of the present application more apparent and understandable, the particular embodiments of the present application are provided below.

### BRIEF DESCRIPTION OF THE DRAWINGS

In order to more clearly illustrate the technical solutions of the embodiments of the present application or the related art, the graphics that are required to describe the embodiments or the related art will be briefly described below. Apparently, the graphics that are described below are merely embodiments of the present application, and a person skilled in the art can obtain other graphics according to these graphics without paying creative work.

FIG. 1 and FIG. 3 are schematic structural diagrams of two display panels according to the related art;

FIG. 2 is a schematic diagram of the capacitance load distribution on the data line of the display panel shown in FIG. 3;

FIG. 4 to FIG. 12 are schematic diagrams of local plane structures of nine display panels according to embodiments of the present application;

FIG. 13 to FIG. 20 are schematic diagrams of plane structures of eight second dummy capacitances according to embodiments of the present application;

FIG. 21 is an analysis curve of the impact of alignment deviation of a data line on the capacitance load according to an embodiment of the present application;

FIG. 22 and FIG. 23 are schematic diagrams of plane structures of another two second dummy capacitances according to embodiments of the present application;

FIG. 24 to FIG. 27 are schematic diagrams of local plane structures of another four display panels according to embodiments of the present application;

FIG. 28 is a schematic structural diagram of a display panel of Z-Inversion technology according to an embodiment of the present application;

FIG. 29 is a graphic design layout of a display panel according to an embodiment of the present application;

FIG. 30 is a schematic structural diagram of a first active area of a display panel according to an embodiment of the present application; and

FIG. 31 and FIG. 32 are schematic diagrams of local plane structures of another two display panels according to embodiments of the present application.

### DETAILED DESCRIPTION

The technical solutions of the embodiments of the present application will be clearly and completely described below with reference to the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall in the protection scope of the present application.

In the drawings, in order for clarity, the thicknesses of the regions and the layers might be exaggerated. In the drawings, the same reference numbers represent the same or similar components, and therefore the detailed description on them are omitted. Moreover, the drawings are merely schematic illustrations of the present application, and are not necessarily drawn to scale.

In the embodiments of the present application, unless otherwise specified, “a plurality of” means two or more; the orientation or positional relationship indicated by the terms “upper” and others are based on the orientation or positional relationship shown in the attached drawings, and are only for the convenience of describing and simplifying the present application, rather than indicating or implying that the structure or element referred to must have a specific orientation, be constructed and operated in a specific orientation, and therefore cannot be understood as a limitation on the present application.

Unless stated otherwise in the context, throughout the description and the claims, the term “comprise” is interpreted as the meaning of opened containing, i.e., “including but not limited to”. In the description of the present disclosure, the terms “one embodiment”, “some embodiments”, “exemplary embodiments”, “example”, “specific example” or “some examples” are intended to indicate that specific features, structures, materials or characteristics related to the embodiment or example are included in at least one embodiment or example of the present application. The illustrative indication of the above terms does not necessarily refer to the same embodiment or example. Moreover, the specific features, structures, materials or characteristics may be included in any one or more embodiments or examples in any suitable manner. In the embodiments of the present application, the use of words such as “first” and

“second” to distinguish identical or similar items with essentially the same function and function is only for the purpose of clearly describing the technical solution of the embodiments of this application, and cannot be understood as indicating or implying relative importance or implying the number of indicated technical features.

The features used in the embodiments of the present application, such as “parallel”, “vertical”, and “identical”, all include strictly defined features such as “parallel”, “vertical”, and “identical”, as well as situations where “roughly parallel”, “roughly vertical”, and “roughly identical” contain certain errors. Considering the measurement and errors related to specific quantities of measurement (such as limitations of measurement systems), which are within the acceptable deviation range for a specific value determined by persons skilled in the art. For example, ‘roughly’ can be expressed within one or more standard deviations, or within 10% or 5% of the stated value. At least one “refers to one or more, and “a plurality of” refers to at least two.

The “same layer” in the embodiment of the present application refers to the relationship between a plurality of film layers formed by the same material after the same step (such as a one-step patterning process). The term “same layer” here does not always mean that the plurality of film layers have the same thickness or have the same height in the cross-sectional diagram. Polygons in the specification are not strictly defined. They can be approximate triangles, parallelograms, trapezoids, pentagon or hexagons, and so on. There may be some small deformations caused by tolerances.

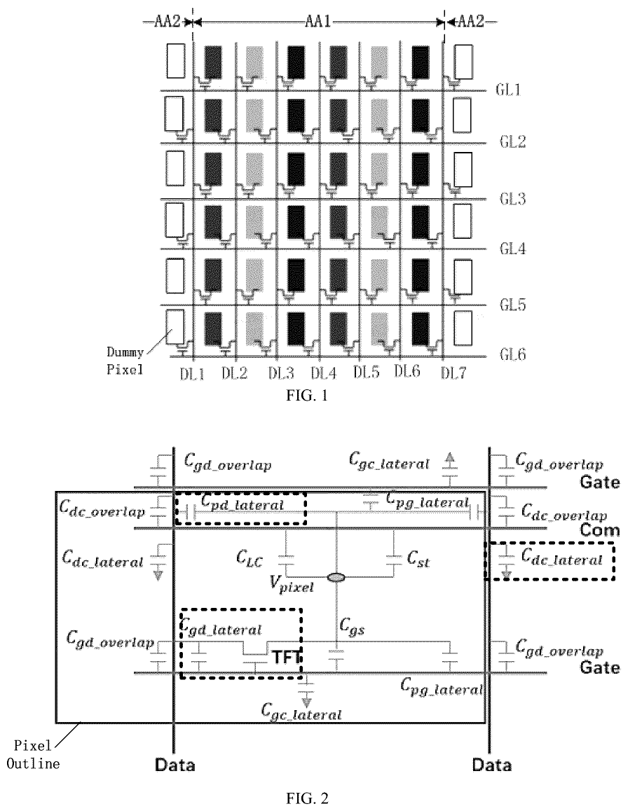

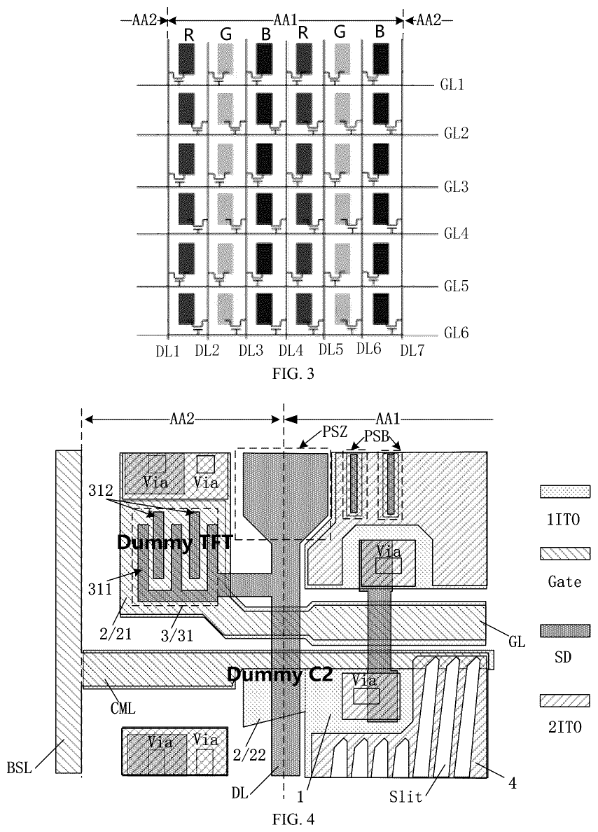

With the continuous development of display technology, people's pursuit of display quality is also increasing. For Z-Inversion technology display products, in order to further reduce the border size of this type of display products, and achieve a product goal of extremely narrow border, the Dummy sub-pixels (Dummy pixel marked in FIG. 1) on outer sides of the first data line and the last data line in the display panel shown in FIG. 1 are removed to obtain the display panel shown in FIG. 3. It should be noted that the outer sides refer to the side close to the surrounding area in the display panel, and the Dummy sub-pixels cannot be displayed in practice.

In addition, in practical applications, due to the special design of the Z-Inversion technology display product, the capacitance load of the first data line and the last data line is inconsistent compared with other data lines. By designing Dummy sub-pixels, the capacitance load of these two data lines can be consistent with other data lines, thereby avoiding the charging rate difference caused by RC signal delay difference, and avoiding the issue of uneven display brightness caused by the charging rate difference.

However, in order to further reduce the border size of this type of display product, after removing the Dummy sub-pixels on the outer sides of the first data line and the last data line, the capacitive load difference increases. Specifically, as shown in FIG. 2, a schematic diagram of the capacitance distribution of sub-pixels in a Z-Inversion display product is provided. Among them, the left side is a normal data line in the active area, and the right side is the first data line or the last data line in the active area. Due to the fact that both sides of the left data line are provided with sub-pixels, while only one side of the right data line is provided with the sub-pixels, the right data line lacks a lateral capacitance between the data line itself and the gate of a transistor in a sub-pixel, as well as an overlapping capacitance (such as Cgd-lateral marked in the dashed box) between the gate of a transistor and the source drain electrode, lacks a lateral capacitance (such as Cdc-lateral marked in the dashed box) between the data line and a common electrode of a sub-pixel, and lacks a lateral capacitance (such as Cpd-lateral marked in the dashed box) between a pixel electrode of a sub-pixel and the data line. The increase in capacitive load difference results in a larger charging rates difference between the two data lines, and the issue of uneven display brightness still exists. Currently, it is difficult to balance narrow borders and uniform display brightness at the same time.

In this regard, embodiments of the present application provide a display panel, and a displaying device. The display panel includes a first active area and at least one second active area, wherein the second active area is located at one side of the first active area, and the display panel further comprises; a substrate; a plurality of sub-pixels located on the substrate and arranged in array, wherein the plurality of sub-pixels are located in the first active area, and each of the plurality of sub-pixels comprises a common electrode; a plurality of grid lines and a plurality of data lines that are located on the substrate, wherein the plurality of grid lines and the plurality of data lines are intersecting and insulated, the plurality of sub-pixels are located at a position defined by the plurality of grid lines and the plurality of data lines, at least one of the data lines is located at a junction of the first active area and the second active area; a plurality of first conductive patterns, wherein the first conductive patterns are at least located in the second active area, and the first conductive patterns are electrically connected to one of the grid lines or the common electrode; and a plurality of second conductive patterns located in the second active area and electrically connected to the at least one of the data lines located at the junction; wherein orthographic projections of part of the first conductive patterns on the substrate overlap with orthographic projections of the second conductive patterns on the substrate. In this way, by setting the projections of some first conductive patterns overlap with the projections of the second conductive patterns, overlapping capacitors are formed, and the second conductive pattern is electrically connected to the data line at the junction, thereby increasing the capacitive load of the data line at the junction and improving the load consistency between the data line at the junction and other data lines. While reducing the border size, the charging rate difference caused by RC signal delay difference is avoided, thereby avoiding the issue of uneven display brightness caused by the charging rate difference, and taking into account narrow borders and higher display effects.

Below, a detailed explanation of the display panel and the display device provided in the embodiment of the present application will be provided in combination with the attached drawings.

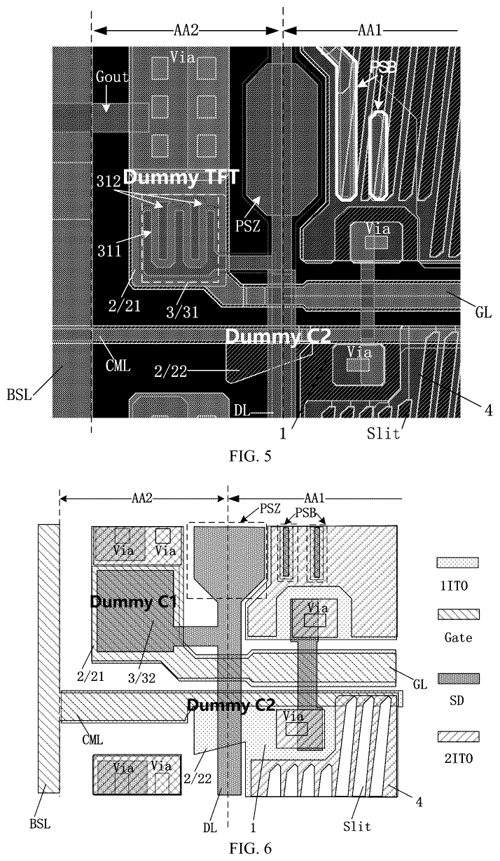

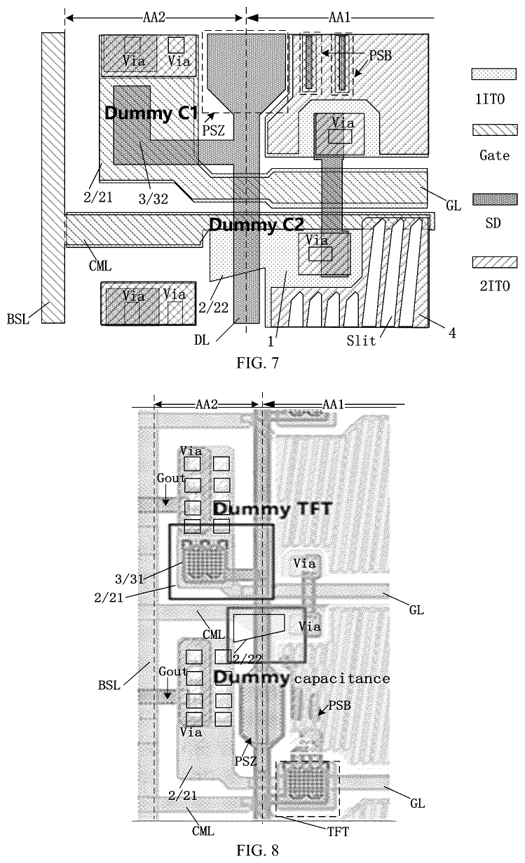

At least one embodiment of the present application provides a display panel, FIG. 4, FIG. 5, FIG. 6, and FIG. 7 are plane schematic diagrams of four display panels provided in the embodiments of the present application. It should be noted that, FIG. 4, FIG. 5, FIG. 6, and FIG. 7 do not show the entire display panel, but only show a partial display panel. The embodiment of the present application does not show a cross-sectional schematic diagram of the layer structure of the display panel, and the layer structure not shown can be referred to in related art.

As shown in FIG. 4, FIG. 5, FIG. 6 or FIG. 7, the display panel includes a first active area AA1 and at least one second active area AA2, wherein the second active area AA2 is located at one side of the first active area AA1, and the display panel further includes;

a substrate;

a plurality of sub-pixels located on the substrate and arranged in array, wherein the plurality of sub-pixels are located in the first active area AA1, and each of the plurality of sub-pixels comprises a common electrode 1;

a plurality of grid lines GL and a plurality of data lines DL that are located on the substrate, wherein the plurality of grid lines GL and the plurality of data lines DL are intersecting and insulated, the plurality of sub-pixels are located at a position defined by the plurality of grid lines GL and the plurality of data lines DL, at least one of the data lines DL is located at a junction of the first active area AA1 and the second active area AA2;

a plurality of first conductive patterns 2, wherein the first conductive patterns 2 are at least located in the second active area AA2, and the first conductive patterns 2 are electrically connected to one of the grid lines GL or the common electrode 1; and

a plurality of second conductive patterns 3 located in the second active area AA2 and electrically connected to the at least one of the data lines DL located at the junction; wherein orthographic projections of part of the first conductive patterns 2 on the substrate overlap with orthographic projections of the second conductive patterns 3 on the substrate.

In an exemplary embodiment, the display panel may be a Liquid Crystal Display (LCD), for example, the LCD may include a Twisted Nematic (TN) type, a Vertical Alignment (VA) type, an In Plane Switching (IPS) type, and an Advanced Super Dimension Switch (ADS) type.

The LCD may include an array baseplate and a color film baseplate. The liquid crystal layer LC is located between the array baseplate and the color film baseplate, and the array baseplate and the color film baseplate respectively include substrates. Among them, the substrates mentioned in the embodiments of the present application refer to the substrates in the array baseplate.

The structures and components included in the array baseplate and the color film baseplate of the above display panel are not limited here, and which may be determined based on the product design.

In some embodiments of the present application, the display panel includes an active area AA and a peripheral area surrounding the active area AA. The active area AA includes the first active area AA1 and at least one second active area AA2, wherein the first active area AA1 includes sub-pixels, the second active area AA2 does not include the sub-pixels. Each sub-pixel in the first active area AA1 is charged and displayed through the data line DL, and the structure in the second active area AA2 assists in improving the charging rate of the data line DL. So that the charging rate of the data line DL located at the junction of the first active area AA1 and the second active area AA2 tends to be consistent with the charging rate of the data line in the first active area AA1.

In some embodiments of the present application, the active area AA may include one first active area AA1 and one second active area AA2, and the second active area AA2 is located on one side of the first active area AA1. At this time, there is a data line DL located at the junction of the first active area AA1 and the second active area AA2.

In other embodiments of the present application, the active area AA may include one first active area AA1 and two second active areas AA2, and the two second active areas AA2 are located on opposite sides of the first active area AA1, respectively. At this time, there are two data lines DL located at two junctions of the first active area AA1 and the second active areas AA2.

In some embodiments of the present application, the Dummy sub-pixel on one side as shown in FIG. 1 can be removed, and the structure in the second active area AA2 provided in the embodiment of the present application can be set. In other embodiments, the Dummy sub-pixels on both sides as shown in FIG. 1 can be removed, and the structure in the second active area AA2 provided in the embodiment of the present application can be set on the both sides.

There is no limitation on the specific materials of the substrates here. Exemplary, the substrate may be any one of silicon, glass, quartz, PET, plastic and other materials.

There is no limitation on the layout of the sub-pixels, which can be determined based on the actual product design.

As an example, the sub-pixels may include three colors of sub-pixels, such as red sub-pixels, green sub-pixels, and blue sub-pixels.

In some embodiments, the sub-pixels of the same color are located in the same row. For example, multiple red sub-pixels are located on the same row, multiple green sub-pixels are located on the same row, and multiple blue sub-pixels are located on the same row. For example, multiple red sub pixels are located in the same column, multiple green sub-pixels are located in the same column, and multiple blue sub-pixels are located in the same column.

In other embodiments, the same row of sub-pixels includes at least two colors of sub-pixels. For example, the same row of sub-pixels can include sub-pixels of two colors, or the same row of sub-pixels can include sub-pixels of three colors.

Here, the shapes of the orthographic projection graphics of the sub-pixels on the substrate are not limited. Generally, the shapes of the orthographic projection graphics of the sub-pixels on the substrate is roughly rectangular, parallelogram, and hexagon.

There are no limitations on the specific structures of the grid lines GL and the data lines DL included in the display panel.

As an example, the grid lines GL can include straight segments or a bent structure formed by multiple straight segments, which can be determined based on the actual design.

As an example, the data lines DL can include straight segments or a bent structure formed by multiple straight segments, which can be determined based on actual design.

There are no limitations on the specific materials of the grid lines GL and data lines DL mentioned above.

As an example, the material of the grid lines GL can include copper, for example, a laminated structure such as MoNb/Cu/MoNb can be formed by sputtering. The material on the side close to the substrate is MoNb, with a thickness of about 300 Å, which is mainly used to improve the adhesion between film layers. The material of an intermediate layer of the laminated structure is Cu, which is the material for the electrical signal transmission channel. And the material on the side away from the substrate 1 is MoNb, with a thickness of about 200 Å, which may be used to protect the intermediate layer and prevent oxidation on the surface of the intermediate layer with low resistivity due to exposure. Due to the fact that the thickness of a single sputtering generally does not exceed 1 μm, when the grid line GL with a thickness exceeding 1 μm is fabricated, it requires multiple sputtering. In addition, it can also be formed through electroplating. Specifically, MoNiTi can be used to form a seed layer to increase the nucleation density of metal grains in subsequent electroplating processes. Then, copper with low resistivity can be produced through electroplating, and an anti-oxidation layer can be made of MoNiTi material.

As an example, the material of the data lines DL can be the same as that of the grid lines GL.

There are no limitations on the specific layer-structure position and specific material of the first conductive pattern 2 in the display panel.

In exemplary embodiments, taking the display panel being the liquid crystal display (LCD) as an example, the LCD includes a first transparent conductive layer (such as 1ITO layer), a gate layer (Gate layer), a source drain metal layer (SD layer), and a second transparent conductive layer (such as 2ITO layer) located on the substrate;

the first transparent conductive layer (such as the 1ITO layer) may directly contact the gate layer (Gate layer), for example, the first transparent conductive layer (such as the 1ITO layer) may be located between the substrate and the gate layer (Gate layer) and directly contact the gate layer (Gate layer). For example, the gate layer may be located between the substrate and the first transparent conductive layer (such as the 1ITO layer) and in direct contact with the gate layer (Gate layer). In addition, the gate layer (Gate layer), the source drain metal layer (SD layer), and the second transparent conductive layer (such as the 2ITO layer) are sequentially arranged in a direction away from the substrate, and insulating materials are arranged between the gate layer (Gate layer) and the source drain metal layer (SD layer), as well as between the source drain metal layer (SD layer) and the second transparent conductive layer (such as the 2ITO layer). The grid lines GL are located in the gate layer (Gate layer), and the data lines DL are located in the source drain metal layer (SD layer). In some embodiments, in order to improve the conductivity of the grid lines GL, auxiliary wirings can be set under the grid lines GL, the auxiliary wirings can be located in the first transparent conductive layer (such as the 1ITO layer), and the orthographic projections of the grid lines GL on the substrate are located within the orthographic projects of the auxiliary wirings on the substrate. The attached drawings provided in the embodiment of the present application are illustrated by setting the auxiliary wirings below the grid lines GL as an example.

In some embodiments, as shown in the positions marked 2/21 in FIG. 4 to FIG. 7, the first conductive pattern 2 is located in the second active area AA2, and the first conductive pattern 2 can be set on the gate layer (Gate layer), and the first conductive pattern 2 is electrically connected to the grid lines GL in the first active area AA1. In practical applications, the first conductive pattern 2 here and the grid lines GL may be an integrated structure.

In other embodiments, as shown in the positions marked 2/22 in FIG. 4 to FIG. 7, a portion of the first conductive pattern 2 is located in the first active area AA1, and a portion of the first conductive pattern 2 is located in the second active area AA2. At this time, the first conductive pattern 2 may be set in the first transparent conductive layer (such as the 1ITO layer), and the first conductive pattern 2 is electrically connected to the common electrode 1 of the sub-pixels in the first active area AA1. In practical applications, the first conductive pattern 2 here and the common electrode 1 may be an integrated structure.

In practical applications, the material of the first conductive pattern 2 can be determined based on the position of the specific layer structure of the first conductive pattern 2 in the display panel.

For example, when the first conductive pattern 2 is located in the gate layer (Gate layer), the material of the first conductive pattern 2 can be the same as that of the gate layer, for example, including copper (Cu).

Exemplary, when the first conductive pattern 2 is located in the first transparent conductive layer, the material of the first conductive pattern 2 can be the same as that of the first transparent conductive layer, for example, including indium tin oxide (ITO). It should be noted that in the attached drawings provided in the embodiment of the present application, the materials of the first transparent conductive layer and the second transparent conductive layer both being indium tin oxide are taken as examples for drawing.

In exemplary embodiments, the second conductive pattern 3 may be located in the source drain metal layer (SD layer).

There are no limitations on the shape of the orthographic projection graphics of the second conductive pattern 3 on the substrate.

In some embodiments, the shape of the orthographic projection graphics of the second conductive pattern 3 on the substrate may be designed as a rectangle as shown in FIG. 6 or FIG. 7, so that the second conductive pattern 3 and the first conductive pattern 2/21 may form an overlapping capacitance, which can simulate the overlapping capacitance formed between the film layers where the gate and the source drain electrode of the transistor in the removed Dummy sub-pixel are located.

In other embodiments, the shape of the orthographic projection graphics of the second conductive pattern 3 on the substrate may be designed to be similar to structures of the source and drain of the transistor. Certainly, the second conductive pattern 3 being designed to be similar to the structures of the source and drain of the transistor may not be completely consistent with the actual structure of the transistor in the first active area AA1.

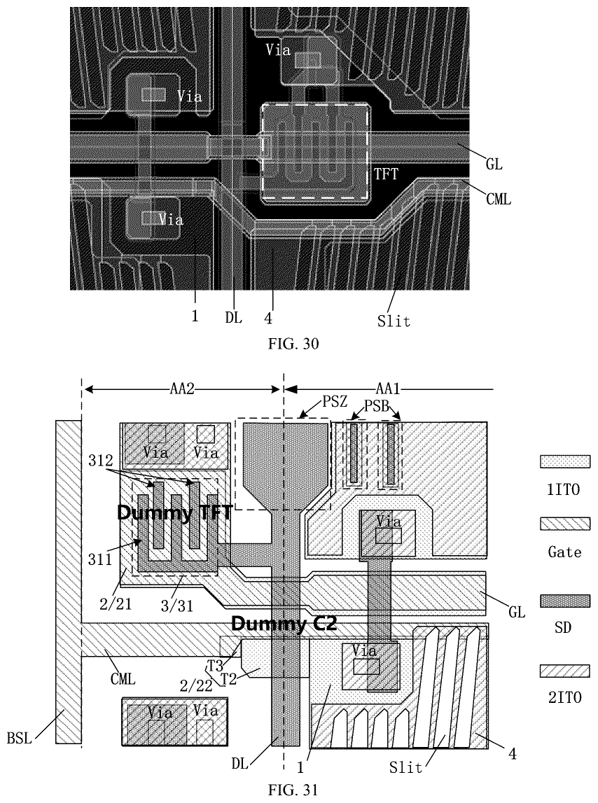

In other embodiments, as shown in FIG. 4 and FIG. 5, the shape of the orthographic projection graphics of the second conductive pattern 3 on the substrate may be designed to be the same as the structure of the transistor in the first active area AA1 shown in FIG. 30, so that the second conductive pattern 3 and the first conductive pattern 2/21 can form a virtual transistor, which may make the capacitive load of the data line DL at the junction as close as possible to the capacitive load of the data line DL in the first active area AA1.

Among them, the orthographic projections of part of the first conductive patterns on the substrate overlap with the orthographic projections of the second conductive patterns on the substrate, including but not limited to the following situations;

firstly, the orthographic projections of part of the first conductive patterns 2 on the substrate partially overlap with the orthographic projections of the second conductive patterns 3 on the substrate;

secondly. outer contours of the orthographic projections of part of the first conductive patterns 2 on the substrate overlap with outer contours of the orthographic projections of the second conductive patterns 3 on the substrate.

Here, part of the first conductive patterns 2 refer to the first conductive patterns 2/21 completely in the second active area AA2 and arranged in the gate layer.

In related art, taking the display panel shown in FIG. 3 as an example, before setting capacitance compensation, the capacitance on the first data line DL1 and the seventh data line DL7 is 258 pF, and the capacitance on the second data line DL2 to the sixth data line DL6 is 410 pF. There is a significant difference in capacitance load, so the charging rates on the first data line DL1 and the seventh data line DL7 are also much greater than those on other data lines. Which results that the brightness of the sub-pixels electrically connected to the first data line DL1 and the seventh data line DL7 is greater than that of the sub-pixels electrically connected to other data lines. resulting in uneven brightness.

In the display panel provided in the embodiment of the present application, by setting that the projections of some first conductive patterns 2 overlap with the projection of the second conductive pattern 3, an overlapping capacitance is formed. The second conductive pattern 3 is electrically connected to the data line at the junction, thereby increasing the capacitive load of the data line at the junction and improving the load consistency between the data line at the junction and other data lines. While reducing the border size, the charging rate difference caused by RC signal delay difference is avoided, thereby avoiding the issue of uneven display brightness caused by the charging rate difference, and taking into account narrow borders and higher display effects.

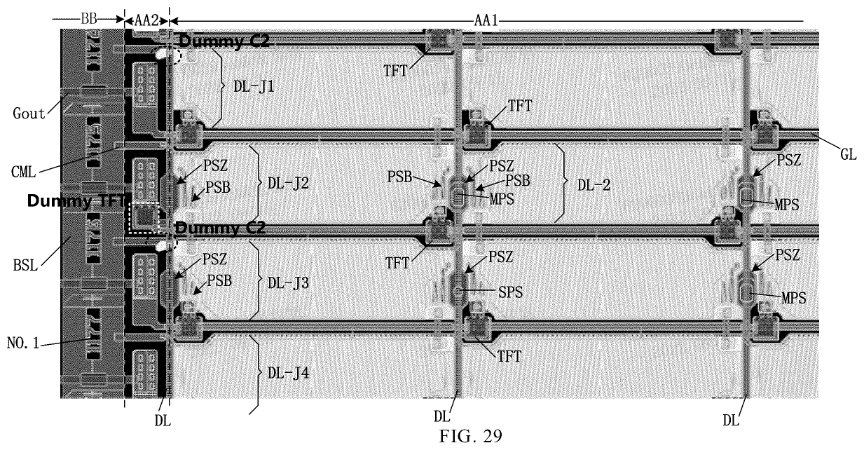

In addition, by setting that the first conductive patterns 2 and the second conductive pattern 3 are in the second active area AA2, and setting that the projections of some first conductive patterns 2 overlap with the projection of the second conductive pattern 3, the overlapping capacitance is formed, which can replace the Dummy sub-pixels in related art. As shown in FIG. 29, the size of the structure in the second active area AA2 is much smaller than the size of the sub-pixels, which may greatly reduce the border size of the display panel, and also ensure a good display effect.

In the display panel provided in the embodiment of the present application. as shown in FIG. 4 to FIG. 7, the plurality of first conductive patterns 2 include a first part 2/21;

the first conductive patterns of the first part 2/21 are located in the second active area AA2 and are electrically connected to the grid lines GL; and the orthographic projections of the second conductive patterns 3 on the substrate are located within orthographic projections of the first conductive patterns of the first part 2/21 on the substrate.

Among them, the orthographic projections of the second conductive patterns 3 on the substrate are located within orthographic projections of the first conductive patterns of the first part 2/21 on the substrate, including but not limited to the following situations;

firstly, the outer contours of the orthographic projections of the second conductive patterns 3 on the substrate are located within outer contours of the orthographic projections of the first conductive patterns of the first part 2/21 on the substrate;

secondly, the outer contours of the orthographic projections of the second conductive patterns 3 on the substrate overlap with the outer contours of the orthographic projections of the first conductive patterns of the first part 2/21 on the substrate.

In the display panel provided in the embodiment of the present application, as shown in FIG. 4 to FIG. 7, the plurality of first conductive patterns 2 include a second part 2/22;

the first conductive patterns of the second part 2/22 extend from the first active area AA1 to the second active area AA2, and are electrically connected to the common electrode 1; orthographic projections of the first conductive patterns of the second part 2/22 on the substrate overlap with an orthographic projection of the data line DL located at the junction on the substrate.

In the display panel provided in the embodiment of the present application, as shown in FIG. 4 to FIG. 7, the outer contours of the orthographic projections of the second conductive patterns 3 on the substrate are located within the outer contours of the orthographic projections of the first conductive patterns of the first part 2/21 on the substrate.

In the display panel provided in the embodiment of the present application, as shown in FIG. 6 and FIG. 7, the second active area AA2 includes a plurality of first dummy capacitances Dummy C1, the first conductive patterns of the first part 2/21 are regarded as first electrodes of the first dummy capacitances Dummy C1, and the second conductive patterns 3/32 are regarded as second electrodes of the first dummy capacitances Dummy C1.

In some embodiments of the present application, by setting that the projections of some first conductive patterns 2 overlap with the projection of the second conductive pattern 3, the plurality of first dummy capacitances Dummy C1 are formed. The second conductive pattern 3 is electrically connected to the data line at the junction, thereby increasing the capacitive load of the data line at the junction and improving the load consistency between the data line at the junction and other data lines. While reducing the border size, the charging rate difference caused by RC signal delay difference is avoided, thereby avoiding the issue of uneven display brightness caused by the charging rate difference, and taking into account narrow borders and higher display effects.

In the display panel provided in the embodiment of the present application, as shown in FIG. 4 and FIG. 5, the second active area includes a plurality of dummy transistors Dummy TFT, gates of the dummy transistors Dummy TFT are electrically connected to the grid lines GL, first ends of the dummy transistors Dummy TFT are electrically connected to the data line DL located at the junction, and second ends of the dummy transistors Dummy TFT are arranged in isolation.

The second ends of the dummy transistors Dummy TFT are arranged in isolation, which refers to the fact that the second ends of the dummy transistors Dummy TFT are a conductive island structure, and this conductive island structure is not electrically connected to other conductive structures.

It should be noted that the first ends may be the source electrode, and the second ends may be the drain electrode. Alternatively, the first ends may be the drain electrode, and the second ends may be the source electrode. The description of the dummy transistors Dummy TFT or the first ends and the second ends of transistors in the following text is similar to the meaning here, and which will not be repeated.

In some embodiments, in order to simplify the design and reduce the complexity of the preparation process, the dummy transistors Dummy TFT may not have an active layer.

In other embodiments, in order to be closer to the design of the transistors in the first active area AA1, the capacitive load of the data line DL located at the junction of the first active area AA1 and the second active area AA2 tends to be closer to the capacitive load of the data line DL located in the first active area AA1. The active layer may be set in the dummy transistors Dummy TFT.

Furthermore, the structures and sizes of the dummy transistors Dummy TFT may be designed to be the same as that of the transistors in the first active area AA1.

In the display panel provided in the embodiment of the present application, the plurality of first dummy capacity Dummy Cl as shown in FIG. 6 and FIG. 7 may be set in a local area, and the dummy transistors Dummy TFT as shown in FIG. 4 and FIG. 5 may be set in a local area.

In the display panel provided in the embodiment of the present application, part regions of the first conductive patterns of the first part 2/21 are regarded as the gates of the dummy transistors Dummy TFT;

at least part of the second conductive patterns 3 includes first conductive parts 311 and second conductive parts 312, the first conductive parts 311 are disconnected from the second conductive parts 312, the first conductive parts 311 are regarded as the first ends of the dummy transistors Dummy TFT, and the second conductive parts 312 are regarded as the second ends of the dummy transistors Dummy TFT.

In an exemplary embodiment, as shown in FIG. 5, the plane figures of the first ends of the dummy transistors Dummy TFT are an “M” shape, and the plane figures of the second ends of the dummy transistors Dummy TFT includes two parts that are not connected to each other.

In practical applications, the structure of the transistors located in the first active area AA1 may be the same as that of the dummy transistors Dummy TFT. However, the two parts of the second ends of the transistors in the first active area AA1 may be electrically connected together and connected to other conductive structures.

It should be noted that in the embodiments of the present application, using Dummy TFT to represent dummy transistors does not limit the dummy transistors to be a Thin Film Transistor (TFT), but can also be a Metal Oxide Semiconductor Field Effect Transistor (MOSFET). The embodiments and attached drawings of the present application both are illustrated by using the dummy transistors as the thin film transistor.

There is no limitation on whether the type of the dummy transistors Dummy TFT located in the second active area AA2 are the same as that of the transistors of the sub-pixels located in the first active area AA1.

In practical applications, on the one hand, in order to reduce the difficulty of the preparation process, and on the other hand, in order to make the capacitive load of the data line at the junction closer to the capacitive load of the data lines in the second active area AA2, it may set that the type of the dummy transistors Dummy TFT and that of the transistors of the sub-pixels in the first active area AA1 are the same.

Among them, at least part of the second conductive patterns 3 includes the first conductive parts 311 and the second conductive parts 312, including but not limited to the following situations;

firstly, a part of the second conductive patterns 3 include the first conductive parts 311 and the second conductive parts 312 that are shown in FIG. 4 and FIG. 5. the first conductive parts 311 are disconnected from the second conductive parts 312. and another part of the second conductive patterns 3 include integrated patterns shown in FIG. 6 and FIG. 7;

secondly, all of the second conductive patterns 3 include the first conductive parts 311 and the second conductive parts 312 that are shown in FIG. 4 and FIG. 5, and the first conductive parts 311 are disconnected from the second conductive parts 312.

In the display panel provided in the embodiment of the present application, the dummy transistors Dummy TFT are provided in the second active area AA2, and the data line DL located at the junction of the first active area AA1 and the second active area AA2 is electrically connected to the first end of the dummy transistors Dummy TFT. In this way, the dummy transistors and the data line DL at the junction can simulate the capacitive load of the data line DL and transistors in the first active area AA1 as much as possible, so that the capacitive load of the data line DL located at the junction of the first active area AA1 and the second active area AA2 tends to be consistent with the capacitive load of the data lines DL located in the first active area AA1. Which may reduce the difference between the charging rate of the data line DL at the junction and the charging rates of the data lines DL in the first active area AA1. While reducing the border size of the display panel, the brightness uniformity of different areas in the display panel is improved, thereby improving the display effect.

In the display panel provided in the embodiment of the present application, a quantity of the dummy transistors Dummy TFT is less than or equal to half a quantity of rows of the sub-pixels.

In an exemplary embodiment, the quantity of the dummy transistors Dummy TFT is equal to half the quantity of rows of the sub-pixels.

In an exemplary embodiment, the quantity of the dummy transistors Dummy TFT is less than half the quantity of rows of the sub-pixels.

In the display panel provided in the embodiment of the present application, as shown in FIG. 3, a partial region of the data line DL (DL1 or DL7) located at the junction of the first active area AA1 and the second active area AA2 is electrically connected to the transistors located in the first active area AA1, while another partial region of the data line DL (DL1 or DL7) located at the junction of the first active area AA1 and the second active area AA2 is not connected to the transistors in the first active area AA1. For the data line DL at the junction that is not connected to the part of line segments of the transistors in the first active area AA1, a dummy transistor Dummy TFT can be set to be electrically connected to it.

In practical applications, in the data line DL (DL1 or DL7) located at the junction of the first active area AA1 and the second active area AA2 of the Z-Inversion class display panel, half of the transistors in the sub-pixels in an adjacent column are electrically connected to it. Therefore, the dummy transistors Dummy TFT with up to half of the total quantity of the sub-pixels of one column can be set to be electrically connected to the data line DL at the junction. Among them, the total quantity of the sub-pixels of one column is the quantity of rows of the sub-pixels.

In the display panel provided in the embodiment of the present application, each of the grid lines GL divides the data line DL located at the junction into a plurality of data line segments; the first active area AA1 includes a plurality of transistors, part of the data line segments is electrically connected to the transistors, at least part of the data line segments that are not connected to the transistors is electrically connected to the dummy transistors Dummy TFT.

It should be noted that in practical applications, the data line DL at the junction is a continuous line. In the specification, for the convenience of describing the invention point, a data line DL is considered as a plurality of data line segments that are connected.

In an exemplary embodiment, at least part of the data line segments that are not connected to the transistors is electrically connected to the dummy transistors Dummy TFT, including but not limited to the following situations;

firstly, part of the data line segments that are not connected to the transistors is electrically connected to the dummy transistors Dummy TFT;

secondly, all of the data line segments that are not connected to the transistors are electrically connected to the dummy transistors Dummy TFT.

In some embodiments of the present application, as shown in FIG. 29, each of the grid lines GL divides the data line DL located at the junction into the plurality of data line segments, for example, the data line segment DL-J1, the data line segment DL-J2, the data line segment DL-J3, and the data line segment DL-J4. Among them, the data line segment DL-J1 is electrically connected to the transistor in the first active area AA1, and the data line segment DL-J3 is electrically connected to the transistor in the first active area AA1. The data line segment DL-J2 and the data line segment DL-J4 are not electrically connected to the transistors in the first active area AA1, however, the data line segment DL-J2 is electrically connected to the dummy transistor Dummy TFT in the second active area AA2.

In this way, the capacitive load of the data line segment DL-J2 tends to be closer to that of the data line segment DL-2 in the first active area AA1, and the capacitive load of the data line DL at the junction tends to be closer to that of the data line DL in the first active area AA1. Thus, the capacitive load of the data line DL located at the junction of the first active area AA1 and the second active area AA2 tends to be consistent with the capacitive load of the data line

DL located in the first active area AA1, which reduces the difference between the charging rate of the data line DL at the junction and the charging rate of the data line DL in the first active area AA1. While reducing the border size of the display panel, it also improves the brightness uniformity of different areas in the display panel, and improves the display effect.

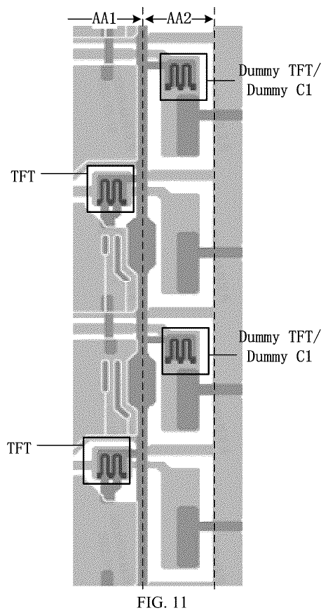

In the display panel provided in the embodiment of the present application. as shown in FIG. 11, the quantity of the dummy transistors Dummy TFT is equal to half the quantity of rows of the sub-pixels, the data line segments that are not connected to the transistors are electrically connected to the dummy transistors Dummy TFT, and the data line segments electrically connected to the transistors and the data line segments electrically connected to the dummy transistors are arranged at intervals.

In this way, the capacitive load of the data line segments of the data line DL located at the junction tends to be closer to that of the data line segments of the data line DL in the first active area AA1, and the overall capacitive load of the data line DL at the junction tends to be closer to that of the data line DL in the first active area AA1. Thus, the capacitive load of the data line DL located at the junction of the first active area AA1 and the second active area AA2 tends to be consistent with the capacitive load of the data line DL located in the first active area AA1, which reduces the difference between the charging rate of the data line DL at the junction and the charging rate of the data line DL in the first active area AA1. While reducing the border size of the display panel, it also improves the brightness uniformity of different areas in the display panel, and improves the display effect.

The data line segments electrically connected to the transistors and the data line segments electrically connected to the dummy transistors are arranged at intervals, which refers to that, for each data line segment of the data line DL at the junction, one of any two adjacent data line segments is electrically connected to the transistor in the first active area AA1, and the other is electrically connected to the dummy transistor Dummy TFT in the second active area AA2. Among them, adjacency refers to the absence of other data line segments between two data line segments.

In some embodiments of the present application. as shown in FIG. 11, each of the grid lines GL divides the data line DL located at the junction into the plurality of data line segments; the first active area AA1 includes the plurality of transistors, part of the data line segments is electrically connected to the transistors, and at least part of the data line segments that are not connected to the transistors is electrically connected to the first dummy capacitances Dummy C1.

Among them, at least part of the data line segments that are not connected to the transistors is electrically connected to the first dummy capacitances Dummy C1, including but not limited to the following situations;

firstly, a part of the data line segments that are not connected to the transistors is electrically connected to the first dummy capacitances Dummy C1;

secondly, all of the data line segments that are not connected to the transistors are electrically connected to the first dummy capacitances Dummy C1.

In some embodiments of the present application, each of the grid lines GL divides the data line DL located at the junction into the plurality of data line segments; the first active area AA1 includes the plurality of transistors, part of the data line segments is electrically connected to the transistors, a part of the data line segments that are not connected to the transistors is electrically connected to the first dummy capacitances Dummy C1, and another part of the data line segments that are not connected to the transistors is electrically connected to the dummy transistors Dummy TFT.

Among them, a quantity of the data line segments that are not connected to the transistors is greater than or equal to the sum of quantities of the first dummy capacitances Dummy C1 and the dummy transistors Dummy TFT.

For example, the quantity of the data line segments that are not connected to the transistors is equal to the sum of the quantities of the first dummy capacitances Dummy C1 and the dummy transistors Dummy TFT.

In some embodiments, the quantity of the dummy transistors Dummy TFT can be set to be greater than or equal to the quantity of the first dummy capacitances Dummy C1. In this way, the overlapping capacitance formed between the gate and the source drain electrode of the dummy transistor Dummy TFT is closer to the overlapping capacitance between the gate and the source drain electrode of the transistor in the first active area AA1, so that the capacitive load of the data line DL located at the junction of the first active area AA1 and the second active area AA2 tends to be consistent with the capacitive load of the data line DL located in the first active area AA1, which reduces the difference between the charging rate of the data line DL at the junction and the charging rate of the data line DL in the first active area AA1. While reducing the border size of the display panel, it also improves the brightness uniformity of different areas in the display panel, and improves the display effect.

In the display panel provided in the embodiment of the present application, as shown in FIG. 4, FIG. 6 and FIG. 7, the first conductive patterns of the second part 2/22 and the common electrode 1 are an integrated structure.

Among them, the meaning of the integrated structure is; using the same material to prepare and form in a single composition process, which refers to processes including mask, film formation, etching, etc.

In the display panel provided in the embodiment of the present application, as shown in FIG. 4 to FIG. 10, the display panel includes a plurality of second dummy capacitances Dummy C2, the first conductive patterns of the second part 2/22 are regarded as first electrodes of the second dummy capacitances Dummy C2 and are electrically connected to the common electrode 1, and part line segments of the data line DL located at the junction are regarded as second electrodes of the second dummy capacitances Dummy C2.

In some embodiments, the display panel includes a plurality of second dummy capacitances Dummy C2, the first conductive patterns of the second part 2/22 are regarded as first electrodes of the second dummy capacitances Dummy C2 and are electrically connected to the grid lines GL, and part line segments of the data line DL located at the junction are regarded as second electrodes of the second dummy capacitances Dummy C2.

It should be noted that the second dummy capacitances Dummy C2 can be electrically connected to the common electrode to compensate for the common electrode signal (Com signal) as an electrode of the second dummy capacitances Dummy C2. Alternatively, the second dummy capacitance Dummy C2 can be electrically connected to the grid lines GL to compensate for the grid lines GL signal (Gate signal) as an electrode of the second dummy capacitances Dummy C2.

In practical applications, due to the fact that the common electrode signal (Com signal) is more stable than the grid line signal (Gate signal), the second dummy capacitances Dummy C2 can be electrically connected to the common electrode to compensate for the common electrode signal (Com signal) as an electrode of the second dummy capacitances Dummy C2.

The compensation signal that can be selected for third dummy capacitances Dummy C3 in the following text is similar to the second dummy capacitances Dummy C2, and which will not be repeated.

In some embodiments, each grid line GL divides the data line DL at the junction into the plurality of data line segments. Part of the data line segments are electrically connected to the dummy transistors Dummy TFT, while another part of the data line segments is provided with second dummy capacitances Dummy C2, which means that the local regions on this part of the data line segments can serve as the second electrodes of the second dummy capacitances Dummy C2.

In some embodiments, as shown in FIG. 4, FIG. 5, FIG. 8, and FIG. 10, there is no second dummy capacitance Dummy C2 set on the data line segments electrically connected to the dummy transistors Dummy TFT, and at least part of the data line segments that are not electrically connected to the dummy transistors Dummy TFT has the second dummy capacitances Dummy C2 set on it.

In some embodiments, the second dummy capacitance Dummy C2 may also be set on the data line segments electrically connected to the dummy transistors Dummy TFT.

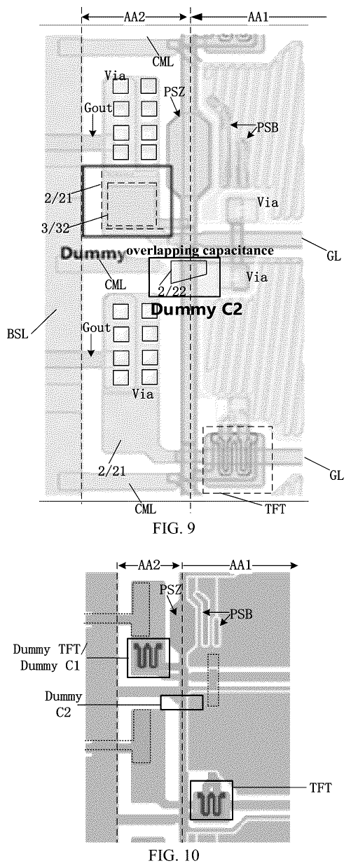

In some embodiments, as shown in FIG. 6, FIG. 7, and FIG. 9, there is no second dummy capacitance Dummy C2 set on the data line segments electrically connected to the first dummy capacitances Dummy C1, and at least part of the data line segments that are not electrically connected to the first dummy capacitances Dummy C1 has the second dummy capacitance Dummy C2 set on it.

In some embodiments, the second dummy capacitance Dummy C2 may also be set on the data line segments electrically connected to the first dummy capacitances Dummy C1.

In some embodiments, as shown in FIG. 4 to FIG. 10, the first electrode (the first conductive patterns of the second part 2/22) of the second dummy capacitance Dummy C2 can be in direct contact with the common electrode line CML (Common Line).

It should be noted that in some embodiments, the common electrode line CML is set on the gate layer (Gate layer). At this time, the first electrode (the first conductive patterns of the second part 2/22) of the second dummy capacitance Dummy C2 can be in direct contact with the common electrode line CML (Common Line), which refers to that the first electrode (the first conductive patterns of the second part 2/22) of the second dummy capacitance Dummy C2 is in direct contact with the common electrode line CML.

In other embodiments. the common electrode line CML includes a portion located in the first transparent conductive layer (such as 1ITO) and another portion located in the gate layer (Gate layer), i.e., the common electrode line CML includes two film layers. At this time, the first electrode (the first conductive patterns of the second part 2/22) of the second dummy capacitance Dummy C2 can be in direct contact with the common electrode line CML (Common Line), which refers to that the first electrode (the first conductive patterns of the second part 2/22) of the second dummy capacitance Dummy C2 is in direct contact with the portion located in the first transparent conductive layer (such as 1ITO) of the common electrode line CML.

In some embodiments, there may be a gap between the first electrode (the first conductive patterns of the second part 2/22) of the second dummy capacitance Dummy C2 and the common electrode line CML (Common Line), and the first electrode (the first conductive patterns of the second part 2/22) of the second dummy capacitance Dummy C2 is electrically connected to the common electrode line CML through the common electrode 1.

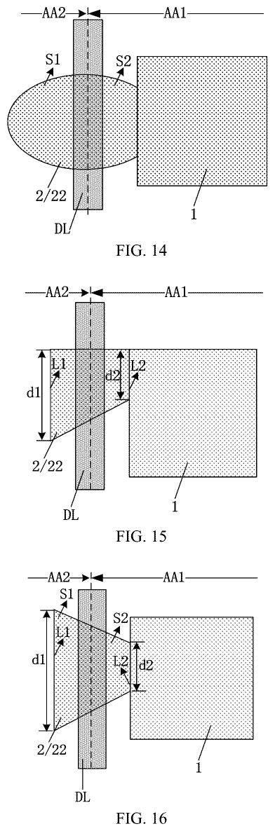

Among them, as shown in FIG. 4 to FIG. 9. FIG. 13 or FIG. 14, an area S1 of an orthographic projection of a part of the first conductive patterns of the second part 2/22 that is located in the second active area AA2 on the substrate is greater than an area of an orthographic projection of a part of the first conductive patterns of the second part 2/22 that is located in the first active area AA1 on the substrate.

It should be noted that the capacitance value of the overlapping capacitance is affected by the area of the two electrodes facing each other of the capacitor, while the capacitance value of the lateral capacitance is less affected by the area of the two electrodes facing each other of the capacitor. In practical applications, the actual position of the data line DL will be affected by the alignment deviation of the preparation process. The second dummy capacitance Dummy C2 includes the overlapping capacitance and the lateral capacitance. Therefore, the overall capacitance value of the second dummy capacitance Dummy C2 may also fluctuate due to the influence of the alignment deviation of the preparation process. In order to balance and reduce the impact of alignment deviation on the overall capacitance value of second dummy capacitance Dummy C2. the embodiment of the present application provides a set of simulated analysis data.

FIG. 21 shows the capacitance changes of the left side capacitance of the second dummy capacitance Dummy C2 (the capacitance formed by the part of the first conductive patterns of the second part 2/22 located in the second active area AA2 and the local region of the data line DL) and the right side capacitance (the capacitance formed by the part of the first conductive patterns of the second part 2/22 located in the first active area AA1 and the local region of the data line DL) shown in FIG. 22 after alignment deviation. Among them. the capacitance value of the lateral capacitance on the left side gradually increases as the data line shifts towards the left (shifts towards the direction from the first active area AA1 points to the second active area AA2); the capacitance value of the lateral capacitance on the right side gradually decreases as the data line shifts towards the left (shifts towards the direction from the first active area AA1 points to the second active area AA2). The sum of the capacitance values of the two lateral capacitances is larger before the critical point M and smaller after the critical point M.

For this purpose, in the implementation example of the present application, the impact of the alignment deviation of the preparation process on the overall capacitance value is compensated by designing the opposite area (also known as the overlap area) of the overlapping capacitance (the intersection of the first conductive patterns of the second part 2/22 and the projection of the data line DL at the junction) in the second dummy capacitance Dummy C2.

Due to the farther the data line DL at the junction is from the common electrode 1, the smaller the capacitance value of the lateral capacitance, the closer the data line DL at the junction is from the common electrode 1, the greater the capacitance value of the lateral capacitance, then, it is possible to design that the overlapping capacitance of the second dummy capacitance Dummy C2 is further away from the common electrode 1, resulting in a larger capacitance value, and the overlapping capacitance of the second dummy capacitance Dummy C2 is closer to the common electrode 1, resulting in a smaller capacitance value. Due to the fact that the capacitance value of the overlapping capacitance in the second dummy capacitance Dummy C2 mainly depends on the overlapping area, and the structural design of the data line

DL at the junction is determined, by designing the shape and size of the first conductive patterns of the second part 2/22, the area S1 of the orthographic projection of part of the first conductive patterns of the second part 2/22 located in the second active area AA2 on the substrate is greater than the area of the orthographic projection of part of the first conductive patterns of the second part 2/22 located in the first active area AA1 on the substrate. In this way, even when the alignment deviation of the preparation process causes the position shift of the data line DL at the junction, the second dummy capacitance Dummy C2 provided in the embodiment of the present application can still provide a stable capacitive load, so that the capacitive load of the data line DL located at the junction of the first active area AA1 and the second active area AA2 tends to be consistent with the capacitive load of the data lines DL located in the first active area AA1. which reduces the difference between the charging rate of the data line DL at the junction and the charging rate of the data line DL in the first active area AA1. While reducing the border size of the display panel, it also improves the brightness uniformity of different areas in the display panel, and improves the display effect.

In the display panel provided in the embodiment of the present application, as shown in FIG. 13 to FIG. 20, graphics of the orthographic projections of the first conductive patterns of the second part 2/22 on the substrate include polygons, arcs, or combinations of the polygons and the arcs.

Exemplary, the polygons may include triangles, quadrilaterals, pentagon, etc. The Arcs may include ellipses, semi ellipses, semi circles, sectors, etc. Among them, half ellipse and half circle not only represent half of an ellipse or circle, but can also be a part of an ellipse or circle.

In the display panel provided in the embodiment of the present application, as shown in FIG. 15 to FIG. 20, graphics of the orthographic projections of the first conductive patterns of the second part 2/22 on the substrate include a first side L1 and a second side L2 that face each other, extension directions of the first side L1 and the second side L2 are the same, the first side L1 is located in the second active area AA2, the second side L2 is located in the first active area AA1, a length d1 of the first side L1 along the extension direction of the first side L1 is greater than or equal to a length d2 of the second side L2 along the extension direction of the second side L2.

In some embodiments, it may set that the length d1 of the first side L1 along the extension direction of the first side L1 is equal to the length d2 of the second side L2 along the extension direction of the second side L2.

In some embodiments, it may set that the length d1 of the first side L1 along the extension direction of the first side L1 is greater than the length d2 of the second side L2 along the extension direction of the second side L2.

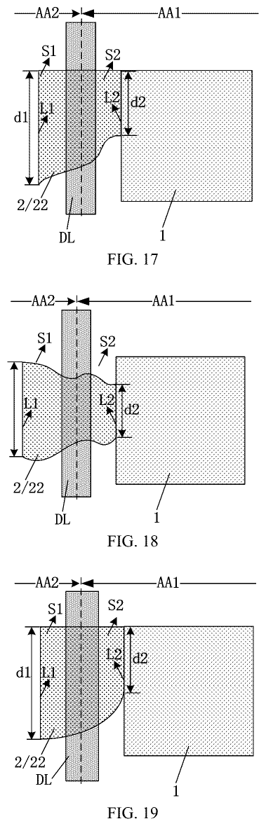

For example, if the length d1 of the first side L1 along its extension direction is greater than the length d2 of the second side L2 along its extension direction, the graphics of the orthographic projection of the first conductive patterns of the second part 2/22 on the substrate may include the right trapezoid as shown in FIG. 15, the isosceles trapezoid as shown in FIG. 16, the figure formed by splicing the right trapezoid with the arc as shown in FIG. 17, the figure obtained by digging out an arc on the right trapezoid, the figure formed by splicing the isosceles trapezoid with two arcs as shown in FIG. 18, the figure formed by splicing the right trapezoid with the arc as shown in FIG. 19. Certainly, other designed graphics can also be included, and which will not be repeated here.

In the display panel provided in the embodiment of the present application, as shown in FIG. 22, in a direction perpendicular to a plane where the substrate is located, a distance from the first conductive patterns of the second part 2/22 to the data line DL located at the junction is a first distance; and the graphics of the orthographic projections of the first conductive patterns of the second part 2/22 on the substrate include a right trapezoid, and a difference y of sizes of an upper bottom and a lower bottom of the right trapezoid is proportional to the first distance.

In an exemplary embodiment, the curve fitting formula for the variation of lateral capacitance with the distance between the data line at the junction is C=a*x+b, where x is the distance and C is the capacitance value. Therefore, for every 1 μm away from the data line, the capacitance decreases by a. That is, a is the difference in capacitance per unit distance, and b is the capacitance in the case of positive alignment.

The known formula for overlapping capacitance is as follows formula (1);

$$C = \frac{{ε}_{0} \cdot {ε}_{r} \cdot A}{d} \qquad formula ( 1 )$$

where ε₀, εᵣ, and d these three parameters are fixed values for the same display panel, where d is the distance between the two electrodes, i.e., the thickness of the insulation layer between the first conductive patterns of the second part 2/22 and the data line DL at the junction; εᵣ is the dielectric constant of the insulation layer between the two electrodes, and ε₀ is a constant. As shown in FIG. 22, in the case of possible positional shift of the data line DL at the junction, the graphics of the orthographic projection of the first conductive patterns of the second part 2/22 on the substrate may be divided into a rectangle with a fixed overlapping area with the data line DL at the junction and a triangle with an unfixed overlapping area with the data line DL at the junction. Assuming that the overlapping area of the rectangle with the fixed overlapping area with the data line DL at the junction is Al, and the overlapping area between the triangle with the unfixed overlapping area with the data line DL at the junction is A2.

Due to the need for the overlapping capacitance to supplement the reduced lateral capacitance, the following formula (2) may be obtained, where A=A1+A2;

$$C = \frac{{ε}_{0} \cdot {ε}_{r} \cdot A}{d} = C = a * x + b \qquad formula ( 2 )$$

According to formula (2), the following formulas may be obtained by calculating;

$$ax = \frac{A 1 * ε 0 * ε r}{d} \qquad formula ( 3 )$$

$$b = \frac{A 2 * ε 0 * ε r}{d} \qquad formula ( 4 )$$

According to formula (3) and formula (4), the following formula may be obtained by calculating;

$$A 2 = bd / ( {ε}_{0} * {ε}_{r} ) = x * y / 2 \qquad formula ( 5 )$$

By incorporating formula (4) into formula (5), the following formula (6) can be obtained;

$$y = 2 * a * d / ( {ε}_{0} * {ε}_{r} ) \qquad formula ( 6 )$$

where y is the difference between the upper bottom and the lower bottom of the graphics of the orthographic projection (right trapezoid) of the first conductive patterns of the second part 2/22 on the substrate as shown in FIG. 22. Due to the fact that in the same area of the same display panel, a, ε₀ and εᵣ are all constant values, then the difference y between the sizes of the upper bottom and the lower bottom of the right trapezoid is proportional to the first distance.

In the display panel provided in the embodiment of the present application, by setting that the graphics of the orthographic projections of the first conductive patterns of the second part 2/22 on the substrate include a right trapezoid, and a difference y of sizes of the upper bottom and the lower bottom of the right trapezoid is proportional to the first distance. In this way, when the alignment deviation of the preparation process causes the position shift of the data line DL at the junction, the second dummy capacitance Dummy C2 provided in the embodiment of the present application can still provide a stable capacitive load, so that the capacitive load of the data line DL located at the junction of the first active area AA1 and the second active area AA2 tends to be consistent with the capacitive load of the data lines DL located in the first active area AA1, which reduces the difference between the charging rate of the data line DL at the junction and the charging rate of the data line DL in the first active area AA1. While reducing the border size of the display panel, it also improves the brightness uniformity of different areas in the display panel, and improves the display effect.

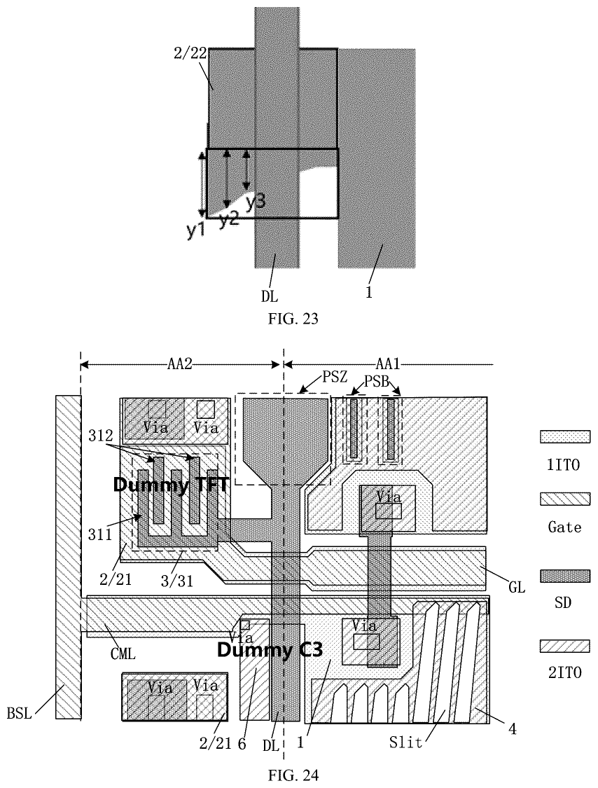

In the display panel provided in the embodiment of the present application, as shown in FIG. 23, in a direction perpendicular to a plane where the substrate is located, a distance from the first conductive patterns of the second part 2/22 to the data line DL located at the junction is a first distance; and the graphics of the orthographic projections of the first conductive patterns of the second part 2/22 on the substrate include a combination of a rectangle and a first graphic, the first graphic includes a plurality of right trapezoids, a right-angle side of each of the plurality of right trapezoids is in contact with the rectangle, and a sum of sizes of an upper bottom and a lower bottom of each of the plurality of right trapezoids is proportional to the first distance.

As shown in FIG. 23, in the case of possible positional shift of the data line DL at the junction, the graphics of the orthographic projection of the first conductive patterns of the second part 2/22 on the substrate may be divided into a rectangle with a fixed overlapping area with the data line DL at the junction and a first graphic with an unfixed overlapping area with the data line DL at the junction. Assuming that the overlapping area of the rectangle with the fixed overlapping area with the data line DL at the junction is A1, and the overlapping area between the first graphic with the unfixed overlapping area with the data line DL at the junction is A2.

Among them, the first graphic includes a combination of the plurality of right trapezoids, the position marked y1 may be the lower bottom of the first right trapezoid, the position marked y2 may be the upper bottom of the first right trapezoid or the lower bottom of the second right trapezoid, and the position marked y3 may be the upper bottom of the second right trapezoid.

Assuming that within the position range of the first right trapezoid, for every 1 μm away from the data line DL at the junction, the capacitance decreases by a1; within the position range of the second right trapezoid, for every 1 μm away from the data line DL at the junction, the capacitance decreases by a2.

By using an algorithm similar to the previous text, we can obtain;

$$y 1 + y 2 = 2 * a 1 * d / ( {ε}_{0} * {ε}_{r} ) \qquad formula ( 7 )$$

$$y 2 + y 3 = 2 * a 2 * d / ( {ε}_{0} * {ε}_{r} ) \qquad formula ( 8 )$$

where y1+y2 is the sum of the sizes of the upper bottom and the lower bottom of the first right trapezoid, and y2+y3 is the sum of the sizes of the upper bottom and the lower bottom of the second right trapezoid. Due to the fact that a1, a2, ε₀ and εᵣ are constant values, the sum of the sizes of the upper bottom and the lower bottom of each right trapezoid is proportional to the first distance.

In the display panel provided in the embodiment of the present application, by setting that the graphics of the orthographic projections of the first conductive patterns of the second part 2/22 on the substrate include a combination of a rectangle and a first graphic, the first graphic includes a plurality of right trapezoids, a right-angle side of each of the plurality of right trapezoids is in contact with the rectangle, and a sum of sizes of an upper bottom and a lower bottom of each of the plurality of right trapezoids is proportional to the first distance. In this way, when the alignment deviation of the preparation process causes the position shift of the data line DL at the junction, the second dummy capacitance Dummy C2 provided in the embodiment of the present application can still provide a stable capacitive load, so that the capacitive load of the data line DL located at the junction of the first active area AA1 and the second active area AA2 tends to be consistent with the capacitive load of the data lines DL located in the first active area AA1, which reduces the difference between the charging rate of the data line DL at the junction and the charging rate of the data line DL in the first active area AA1. While reducing the border size of the display panel, it also improves the brightness uniformity of different areas in the display panel, and improves the display effect.

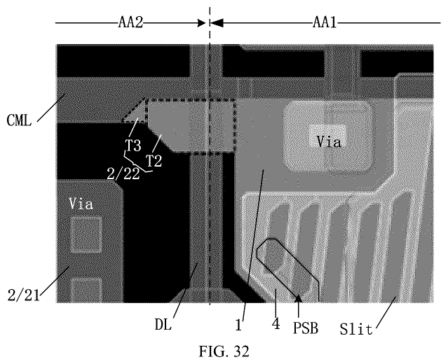

In the display panel provided in the embodiment of the present application, as shown in FIG. 31 and FIG. 32, graphics of the orthographic projections of the first conductive patterns of the second part 2/22 on the substrate include a combination of a second graphic T2 and a third graphic T3 that are connected, the second graphic T2 includes a chamfered rectangle, and the third graphic T3 includes a polygon, an arc, or a combination of the polygon and the arc;

where the second graphic T2 extends from the first active area AA1 to the second active area AA2. the third graphic T3 is located in the second active area AA2, a part of the first conductive patterns of the second part 2/22 whose orthographic projection is the third graphic T3 is in directly contact with a common electrode line CML of the display panel, and a chamfer of the chamfered rectangle is located in the second active area AA2.

There is no limitation on the size of the chamfer in the chamfered rectangle. However, regardless of the size of the chamfer in the chamfered rectangle, the area of a portion of the second graphic T2 located in the second active area AA2 is always greater than the area of a portion of the second graphic T2 located in the first active area AA1.

In addition, it should be noted that in practical applications, even if the position of the data line DL at the junction shifts due to the alignment deviation during the preparation process, the data line DL at the junction hardly shifts to the position of the third graphic T3. Therefore, the capacitance value of the overlapping capacitance of the second dummy capacitance Dummy C2 is mainly determined by the size of the second graphic T2.

In the embodiment of the present application, for the portion of the second graphic T2 located in the second active area AA2, when the second graphic T2 is a rectangle, a chamfer may be set at the top corner closest to the conductive pattern (such as the first conductive patterns of the first part 2/21 shown in FIG. 32) with gate signal in the rectangle. On the one hand, the distance between the second graphic T2 and the conductive pattern with gate signals may be increased, which may avoid interference from the gate signals on signals in the second graphic T2. On the other hand, the sharp conductive pattern on the first conductive patterns of the second part 2/22 that increases the probability of electrostatic breakdown may be avoided, thereby improving the stability of signal transmission in the display panel, and improving the reliability of the display panel.

In addition, the third graphic T3 includes polygons, arcs, or a combination of the polygons and the arcs.

The polygons may include triangles, quadrangles (rectangle, diamond, parallelogram), pentagon, hexagons, etc. The arcs may include circles, ellipses, semi circles, semi ellipses, etc.

The combination of the polygons and the arcs includes; graphics formed by splicing the polygons and the arcs, or graphics formed by removing local areas on the polygons or the arcs.

It should be noted that FIG. 3 shows a partial region of a display panel design layout. Due to the common electrode line CML covering the third graphic T3, some regions of the third graphic T3 are covered, so the exposed part of the third graphic T3 in FIG. 3 is a triangle. In practical applications, the third graphic T3 may be of other shapes, the part of the first conductive patterns of the second part 2/22 whose orthographic projection is the third graphic T3, is mainly used to directly contact and overlap with the common electrode line CML, to achieve the purpose of electrical connection.

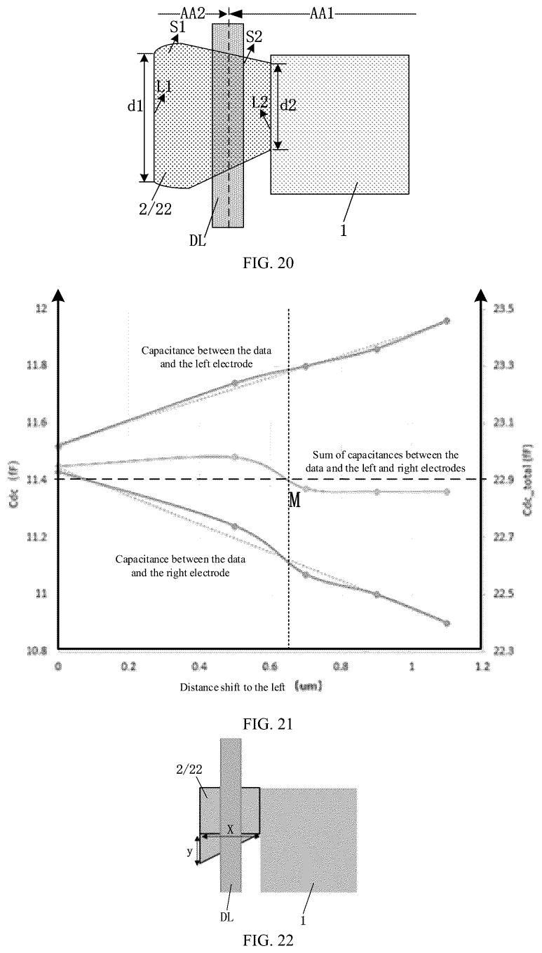

In the display panel provided in the embodiment of the present application, as shown in FIG. 20, vertex angles of graphics of the orthographic projections of the first conductive patterns of the second part 2/22 on the substrate include a round corner.

In some embodiments of the present application, since part regions of the first conductive patterns of the second part 2/22 are located in the second active area AA2, and the second active area AA2 is close to the non-active area, the non-active area is prone to electrostatic breakdown, and the conductive pattern with sharp structure will aggravate the electrostatic breakdown, causing damage to the display panel. When designing the first conductive patterns of the second part 2/22, sharp corners are avoided as much as possible and it may be designed as a rounded corner, thereby reducing the possibility of electrostatic breakdown in this region and improving the quality and reliability of the display panel.

In the display panel provided in the embodiment of the present application, a quantity of the second dummy capacitance Dummy C2 is greater than or equal to half a quantity of rows of the sub-pixels.

In exemplary embodiments, the quantity of the second dummy capacitance Dummy C2 may be greater than half the quantity of rows of the sub-pixels, and less than or equal to the quantity of rows of the sub-pixels.

For example, the quantity of the second dummy capacitance Dummy C2 may be equal to the quantity of rows of the sub-pixels.

In exemplary embodiments, the quantity of the second dummy capacitance Dummy C2 may be equal to half the quantity of rows of the sub-pixels.

In the display panel provided in the embodiment of the present application, as shown in FIG. 8. FIG. 9 and FIG. 29, each of the grid lines GL divides the data line DL located at the junction into a plurality of data line segments; orthographic projections of at least part of the data line segments on the substrate overlap with the orthographic projections of the first conductive patterns of the second part 2/22 on the substrate.

In some embodiments of the present application, as shown in FIG. 29, each of the grid lines GL divides the data line DL located at the junction into the plurality of data line segments. for example, the data line segment DL-J1, the data line segment DL-J2, the data line segment DL-J3, and the data line segment DL-J4. Among them, the data line segment DL-J3 is electrically connected to the transistor in the first active area AA1, and the data line segment DL-J3 is electrically connected to the second dummy capacitance Dummy C2. The data line segment DL-J2 is electrically connected to the dummy transistor Dummy TFT in the second active area AA2, and the data line segment DL-J2 is not electrically connected to the second dummy capacitance Dummy C2.

In some embodiments of the present application, the same data line segment may be electrically connected to both the dummy transistor Dummy TFT and the second dummy capacitance Dummy C2.

In some embodiments of the present application, the same data line segment may be electrically connected to both the transistor in the first active area AA1 and the second dummy capacitance Dummy C2.

However, the same data line segment cannot be electrically connected to both the transistor in the first active area AA1 and the dummy transistor Dummy TFT.

In some embodiments of the present application, the same data line segment may be electrically connected to both the first dummy capacitance Dummy C1 and the second dummy capacitance Dummy C2.

In some embodiments of the present application, the same data line segment may be electrically connected to both the transistor in the first active area AA1 and the second dummy capacitance Dummy C2.

However, the same data line segment cannot be electrically connected to both the transistor in the first active area AA1 and the first dummy capacitance Dummy C1.

Among them, the orthographic projections of at least part of the data line segments on the substrate overlap with the orthographic projections of the first conductive patterns of the second part 2/22 on the substrate, including but not limited to the following situations;

firstly, the orthographic projections of a part of the data line segments on the substrate overlap with the orthographic projections of the first conductive patterns of the second part 2/22 on the substrate. that is to say, the part of the data line segments may be electrically connected to the second dummy capacitance Dummy C2.

Secondly, the orthographic projections of all of the data line segments on the substrate overlap with the orthographic projections of the first conductive patterns of the second part 2/22 on the substrate. that is to say. all of the data line segments may be electrically connected to the second dummy capacitance Dummy C2.

In some embodiments of the present application, by setting the second dummy capacitance Dummy C2 to simulate the lateral capacitance formed between the data lines DL and the common electrode in the first active area AA, the capacitive load of the data line DL located at the junction of the first active area AA1 and the second active area AA2 tends to be consistent with the capacitive load of the data lines DL located in the first active area AA1, which reduces the difference between the charging rate of the data line DL at the junction and the charging rate of the data line DL in the first active area AA1. While reducing the border size of the display panel, it also improves the brightness uniformity of different areas in the display panel, and improves the display effect.

In the display panel provided in the embodiment of the present application, the quantity of the second dummy capacitance Dummy C2 is equal to the quantity of rows of the sub-pixels, the orthographic projections of the data line segments on the substrate overlap with the orthographic projections of the first conductive patterns of the second part 2/22 on the substrate. At this time, every data line segment at the junction of the first active area AA1 and the second active area AA2 is provided with the second dummy capacitance Dummy C2.

In an exemplary embodiment, the shape and size of the plane graphics of the first electrode (the first conductive patterns of the second part 2/22) of each second dummy capacitance Dummy C2 set on each data line segment at the junction are the same, and the shape and size of the plane graphics of each data line segment overlapped with the orthographic projection of the first conductive patterns of the second part 2/22 on the substrate are also the same.

It should be noted that by setting the second dummy capacitance Dummy C2 on each data line segment at the junction of the first active area AA1 and the second active area AA2, the capacitive load of each data line segment at the junction tends to be closer to that of the data line segment in the first active area AA1, thereby making the overall capacitive load of the data line DL at the junction tends to be closer to the capacitive load of the data line DL located in the first active area AA1, which reduces the difference between the charging rate of the data line DL at the junction and the charging rate of the data line DL in the first active area AA1. While reducing the border size of the display panel, it also improves the brightness uniformity of different areas in the display panel, and improves the display effect.

In the display panel provided in the embodiment of the present application, the quantity of the second dummy capacitance Dummy C2 is equal to half the quantity of rows of the sub-pixels, orthographic projections of half of the data line segments on the substrate overlap with the orthographic projections of the first conductive patterns of the second part 2/22 on the substrate.

In some embodiments, one second dummy capacitance Dummy C2 may be set on each data line segment in the local region of the data line DL at the junction of the display panel. In another local region of the data line DL at the junction, no second dummy capacitance Dummy C2 is set.

In some embodiments, for every two adjacent data line segments of the data line DL at the junction, one second dummy capacitance Dummy C2 is set on one of the data line segments. and no second dummy capacitance Dummy C2 is set on the other data line segment.

In some embodiments, for each data line segment of the data line DL at the junction, one second dummy capacitance Dummy C2 may be set on the first data line segment, one second dummy capacitance Dummy C2 may be set on the second data line segment, no second dummy capacitance Dummy C2 is set on the third data line segment, one second dummy capacitance Dummy C2 may be set on the fourth data line segment, one second dummy capacitance Dummy C2 may be set on the fifth data line segment, and no second dummy capacitance Dummy C2 is set on the sixth data line segment. And cycle through the settings in sequence.

In some embodiments, for each data line segment of the data line DL at the junction, one second dummy capacitance Dummy C2 may be set on the first data line segment, no second dummy capacitance Dummy C2 is set on the second data line segment, no second dummy capacitance Dummy C2 is set on the third data line segment, one second dummy capacitance Dummy C2 may be set on the fourth data line segment, no second dummy capacitance Dummy C2 is set on the fifth data line segment, and no second dummy capacitance Dummy C2 is set on the sixth data line segment. And cycle through the settings in sequence.

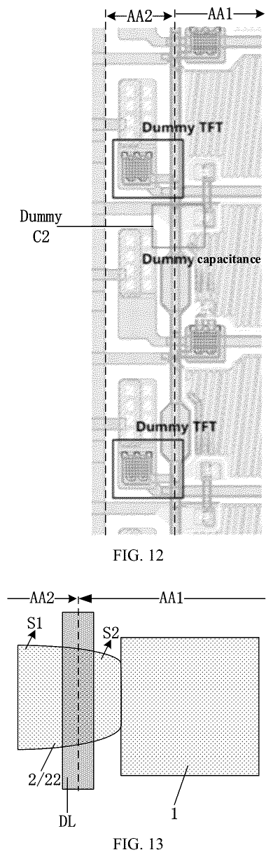

In the display panel provided in the embodiment of the present application, as shown in FIG. 10. FIG. 12 and FIG. 29, each of the data line segments includes a first group and a second group, orthographic projections of data line segments of the first group on the substrate overlap with the orthographic projections of the first conductive patterns of the second part 2/22 on the substrate, orthographic projections of data line segments of the second group on the substrate do not overlap with the orthographic projections of the first conductive patterns of the second part 2/22 on the substrate; wherein the data line segments of the first group and the data line segments of the second group are arranged at intervals. It can be understood that at this point, the second dummy capacitances Dummy C2 are set at intervals on each data line segment. That is, one second dummy capacitance Dummy C2 is set on the first data segment, and no second dummy capacitance Dummy C2 is set on the second data segment, one second dummy capacitance Dummy C2 is set on the third data segment, and no second dummy capacitance Dummy C2 is set on the fourth data segment.

In the display panel provided in the embodiment of the present application, there is a capacitive load difference between the data line at the junction and the data line in the first active area. When the second dummy capacitances Dummy C2 are arranged at intervals on each data line segment, one second dummy capacitance Dummy C2 may be set to simultaneously compensate for the capacitive load difference between two data line segments.

For example, if the capacitive load between a data line segment and a common electrode located in the first active area AA1 is R1, and the second dummy capacitances Dummy C2 are arranged at intervals on each data line segment, then the capacitive load of the second dummy capacitance set on a data line segment at the junction may be 2R1. In this way, the sum of the capacitive loads of each data line segment included in a data line DL located in the first active area AA1 and the sum of the capacitive loads of the second dummy capacitance Dummy C2 set on each data line segment DL located at the junction tend to be equal, so that the overall capacitive load of the data line DL at the junction tends to be closer to the capacitive load of the data line DL located in the first active area AA1, which reduces the difference between the charging rate of the data line DL at the junction and the charging rate of the data line DL in the first active area AA1. While reducing the border size of the display panel, it also improves the brightness uniformity of different areas in the display panel, and improves the display effect.

In the display panel provided in the embodiment of the present application, as shown in FIG. 24 to FIG. 27. the display panel further includes a third conductive pattern 6, the third conductive pattern 6 is electrically connected to the common electrode 1, the third conductive pattern 6 is at least located in the second active area AA2, and at least part region of the third conductive pattern AA2 is located between the first conductive patterns of the first part 2/21 and the data line located at the junction; wherein an orthographic projection of the at least part region of the third conductive pattern 6 on the substrate does not overlap with the orthographic projection of the data line DL located at the junction on the substrate.

For example. as shown in FIG. 24 to FIG. 27, the third conductive pattern 6 may be set on the same layer as a pixel electrode 4, where a slit is set in the pixel electrode 4.

As an example, the third conductive pattern 6 may be set on the same layer as the common electrode 1.

Among them, the third conductive pattern 6 is located at least in the second active area AA2, including but not limited to the following situations;

firstly, as shown in FIG. 24 and FIG. 26, the third conductive pattern 6 is located in the second active area AA2;

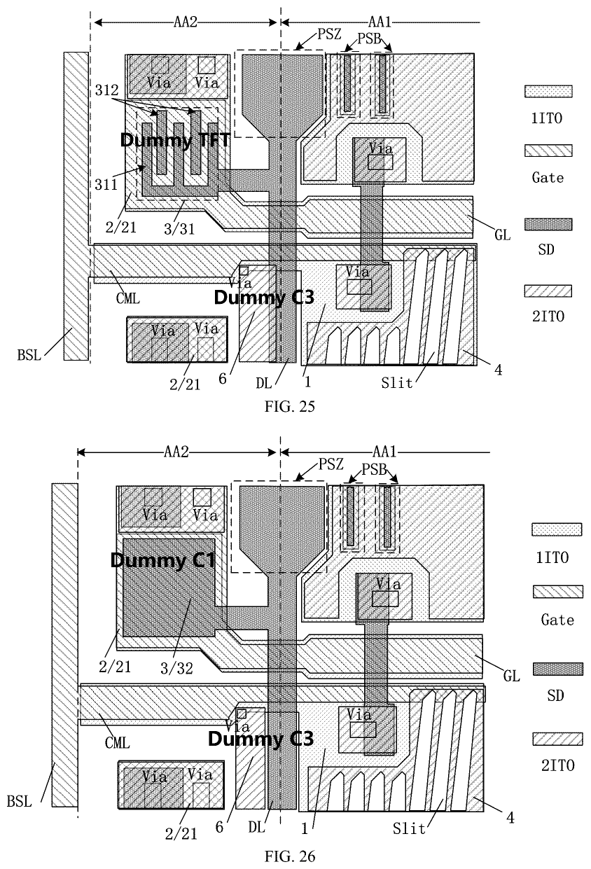

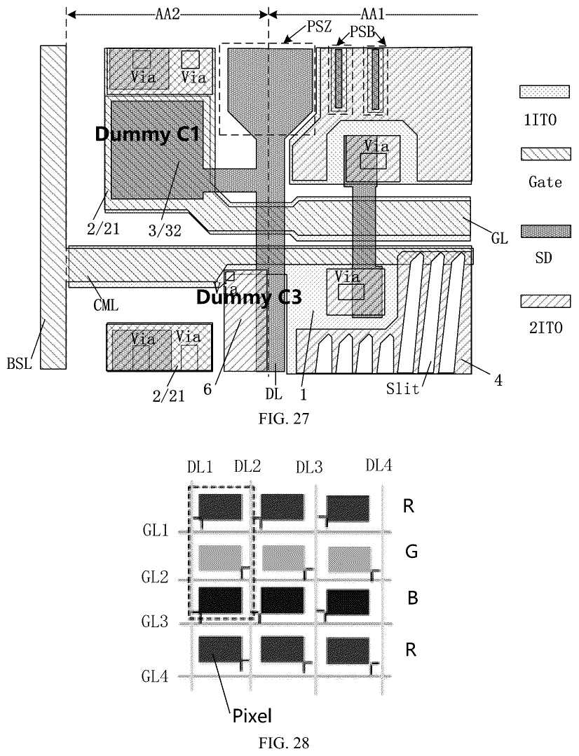

secondly, as shown in FIG. 25 and FIG. 27, the third conductive pattern 6 is not only located in the second active area AA2, but also extends to the first active area AA1. At this point, the main part of the third conductive pattern 6 is located in the second active area AA2, while the local part of the third conductive pattern 6 is located in the first active area AA1.

In addition, at least part region of the third conductive pattern 6 are located between the first conductive patterns of the first part 2/21 and the data line DL at the junction, including but not limited to the following situations;

firstly, as shown in FIG. 25 and FIG. 27, a part region of the third conductive pattern 6 is located between the first conductive patterns of the first part 2/21 and the data line DL at the junction;

secondly, as shown in FIG. 24 and FIG. 26, the third conductive pattern 6 is completely located between the first conductive patterns of the first part 2/21 and the data line DL at the junction.

It should also be noted that the orthographic projection of the at least part region of the third conductive pattern 6 on the substrate does not overlap with the orthographic projection of the data line DL located at the junction on the substrate, including but not limited to the following situations;

firstly, as shown in FIG. 25 and FIG. 27, the orthographic projection of a part region of the third conductive pattern 6 on the substrate does not overlap with the orthographic projection of the data line DL located at the junction on the substrate;

secondly, as shown in FIG. 24 and FIG. 26, the orthographic projection of the third conductive pattern 6 on the substrate does not overlap with the orthographic projection of the data line DL located at the junction on the substrate.

In the display panel provided in the embodiment of the present application, as shown in FIG. 24 to FIG. 27, the display panel further includes a third dummy capacitance Dummy C3, the third conductive pattern 6 is regarded as a first electrode of the third dummy capacitance Dummy C3 and is electrically connected to the common electrode 1, part line segments of the data line DL located at the junction are regarded as a second electrode of the third dummy capacitance Dummy C3.

In some embodiments of the present application, as shown in FIG. 24 and FIG. 26, the third dummy capacitance Dummy C3 includes a lateral capacitance.

In some embodiments of the present application, as shown in FIG. 25 and FIG. 27, third dummy capacitance Dummy C3 includes the lateral capacitance and the overlapping capacitance.

In the display panel provided in the embodiment of the present application, as shown in FIG. 24 and FIG. 26, an orthographic projection of the third conductive pattern 6 on the substrate does not overlap with the orthographic projection of the data line DL located at the junction on the substrate.

In some embodiments of the present application, the quantity of the third dummy capacitance Dummy C3 is less than or equal to the quantity of rows of the sub-pixels.

As an example, the quantity of the third dummy capacitance Dummy C3 is equal to the quantity of rows of the sub-pixels.

As an example, the quantity of the third dummy capacitance Dummy C3 is less than the quantity of rows of the sub-pixels.

In the display panel provided in the embodiment of the present application, each grid line GL divides the data line DL at the junction into the plurality of data line segments, and one third dummy capacitance Dummy C3 may be set at every position between the first conductive patterns of the first part 2/21 and the data line segments.

In some embodiments, as shown in FIG. 24 and FIG. 25, the data line segments may be set in a part region of the display panel to be electrically connected to the dummy transistor Dummy TFT, and the data line segments may be set in a part region of the display panel to be electrically connected to the third dummy capacitance Dummy C3.

In some embodiments, as shown in FIG. 26 and FIG. 27, the data line segments may be set in a part region of the display panel to be electrically connected to the first dummy capacitance Dummy C1, and the data line segments may be set in a part region of the display panel to be electrically connected to the third dummy capacitance Dummy C3.

In some embodiments, the data line segments may be set in a part region of the display panel to be electrically connected to the first dummy capacitance Dummy C1, the data line segments may be set in a part region of the display panel to be electrically connected to the dummy transistor Dummy TFT, and the data line segments may be set in a part region of the display panel to be electrically connected to the third dummy capacitance Dummy C3.

In some embodiments, the data line segments may be set in a part region of the display panel to be electrically connected to the first dummy capacitance Dummy C1, the data line segments may be set in a part region of the display panel to be electrically connected to the dummy transistor Dummy TFT, the data line segments may be set in a part region of the display panel to be electrically connected to the second dummy capacitance Dummy C2, and the data line segments may be set in a part region of the display panel to be electrically connected to the third dummy capacitance Dummy C3.

In some embodiments, the same data line segment can be set to be electrically connected to both the second dummy capacitance Dummy C2 and the third dummy capacitance Dummy C3. It should be noted that in the case of setting both second dummy capacitance Dummy C2 and the third dummy capacitance Dummy C3 at the corresponding positions of the same data line segment, there is a certain distance between the planar shapes of the second dummy capacitance Dummy C2 and the third dummy capacitance Dummy C3 to avoid electrical signal interference between the two dummy capacitances.

In some embodiments, for every two adjacent data line segments of the data line DL at the junction, one third dummy capacitance Dummy C3 is set on one of the data line segments. and no third dummy capacitance Dummy C3 is set on the other data line segment.

In some embodiments, for each data line segment of the data line DL at the junction, one third dummy capacitance Dummy C3 may be set on the first data line segment, one third dummy capacitance Dummy C3 may be set on the second data line segment, no third dummy capacitance Dummy C3 is set on the third data line segment, one third dummy capacitance Dummy C3 may be set on the fourth data line segment, one third dummy capacitance Dummy C3 may be set on the fifth data line segment, and no third dummy capacitance Dummy C3 is set on the sixth data line segment. And cycle through the settings in sequence.

In some embodiments, for each data line segment of the data line DL at the junction, one third dummy capacitance Dummy C3 may be set on the first data line segment, no third dummy capacitance Dummy C3 is set on the second data line segment, no third dummy capacitance Dummy C3 is set on the third data line segment, one third dummy capacitance Dummy C3 may be set on the fourth data line segment, no third dummy capacitance Dummy C3 is set on the fifth data line segment, and no third dummy capacitance Dummy C3 is set on the sixth data line segment. And cycle through the settings in sequence.

In the embodiment of the present application, the third dummy capacitance Dummy C3 electrically connected to the data line DL at the junction, can simulate the lateral capacitance formed between the common electrode 1 and the data line DL located in the first active area AA1. So that the overall capacitive load of the data line DL located at the junction approaches the capacitive load of the data line DL located in the first active area AA1, which reduces the difference between the charging rate of the data line DL at the junction and the charging rate of the data line DL in the first active area AA1. While reducing the border size of the display panel, it also improves the brightness uniformity of different areas in the display panel, and improves the display effect.

In the display panel provided in the embodiment of the present application, the sub-pixels in a same row are connected to the same grid line GL; a column of the sub-pixels are provided between every two adjacent data lines DL, the sub-pixels in a same column includes a first category and a second category, any one of the sub-pixels of the first category is located between two sub-pixels of the second category, wherein the first category of the sub-pixels in the same column is electrically connected to one data line DL, the second category of the sub-pixels in the same column is electrically connected to another data line DL.

As shown in FIG. 28, the sub-pixels in the first row are connected to the first grid line GL1, the sub-pixels in the second row are connected to the second grid line GL2, the sub-pixels in the third row are connected to the third grid line GL3, and the sub-pixels in the fourth row are connected to the fourth grid line GL4.

As shown in FIG. 28, the first sub-pixel and the third sub-pixel in the first column are connected to the first data line DL1, and the second sub-pixel and the fourth sub-pixel in the first column are connected to the second data line DL2. The first sub-pixel and the third sub-pixel in the second column are connected to the second data line DL2, and the second sub-pixel and the fourth sub-pixel in the second column are connected to the third data line DL3. The first sub-pixel and the third sub-pixel in the third column are connected to the third data line DL3, and the second sub-pixel and the fourth sub-pixel in the third column are connected to the fourth data line DL4. The display panel shown in FIG. 28 is a display panel of Z-Inversion technology. The specific introduction of the display panel of Z-Inversion technology can be found in the related art, and which will not be repeated here.

Among them, the first data line DL1 and the fourth data line DL4 are the data lines located at the junction of the first active area AA1 and the second active area AA2, respectively, and the quantity of the transistors of the sub-pixels electrically connected to these two data lines is half of the quantity of the transistors of the sub-pixels connected to other data lines. For the display panel of Z-Inversion technology, there is at least one data line located at the junction, and the quantity of the transistors of the sub-pixels electrically connected to the at least one data line is half of the quantity of the transistors of the sub-pixels connected to other data lines.

In some embodiments of the present application, the sub-pixels in the first row may be set as red sub-pixels, the sub-pixels in the second row may be set as green sub-pixels, the sub-pixels in the third row may be set as green sub-pixels, and the sub-pixels in the fourth row may be set as red sub-pixels.

In some embodiments of the present application, it may also set the sub-pixels in the first column as red sub-pixels, the sub-pixels in the second column as green sub-pixels, and the sub-pixels in the third column as green sub-pixels.

In the display panel provided in the embodiment of the present application, as shown in FIG. 4 to FIG. 7 and FIG. 29, the plurality of grid lines GL divide the data lines DL in the first active area AA1 into a plurality of data line segments, in the plurality of data line segments, part of the data line segments include support parts PSZ, first connecting parts and second connecting parts, the support parts PSZ are located between the first connecting parts and the second connecting parts;

where orthographic projections of the first connecting parts on the substrate overlap with the orthographic projection of one grid line GL on the substrate, and orthographic projections of the second connecting parts on the substrate overlap with the orthographic projection of another grid line GL on the substrate.

A size of each of the support parts PSZ in a direction perpendicular to an extension direction of the data line segment is greater than a size of each of the first connecting parts in the direction perpendicular to the extension direction of the data line segment, and the size of each of the support parts in the direction perpendicular to the extension direction of the data line segment is greater than a size of each of the second connecting part in the direction perpendicular to the extension direction of the data line segment. It can be understood that the line width of the support part in the data line segment is greater than the line width of the first connecting part, and the line width of the support part is greater than the line width of the second connecting part.

In exemplary embodiments, the line width of the first connecting part can be the same as that of the second connecting part.

In some embodiments, as shown in FIG. 29, in the local region of the data line DL, two connected data line segments are both provided with the support parts PSZ, the first connecting parts, and the second connecting parts.

In some embodiments, in the local region of the data line DL, the support parts PSZ, the first connecting parts, and the second connecting parts may be set at intervals.

For example, for the same data line DL, the first data line segment is provided with the support part PSZ, the first connecting part, and the second connecting part; the second data line segment is not provided with the support part PSZ, the first connecting part, and the second connecting part; and the third data line segment is provided with the support part PSZ, the first connecting part, and the second connecting part.

For example, the first data line segment is provided with the support part PSZ, the first connecting part, and the second connecting part; the second data line segment is not provided with the support part PSZ, the first connecting part, and the second connecting part; the third data line segment is not provided with the support part PSZ, the first connecting part, and the second connecting part; the fourth data line segment is not provided with the support part PSZ, the first connecting part, and the second connecting part; and the fifth data line segment is not provided with the support part PSZ, the first connecting part, and the second connecting part;

the sixth data line segment is provided with the support part PSZ, the first connecting part, and the second connecting part; the seventh data line segment is not provided with the support part PSZ, the first connecting part, and the second connecting part; the eighth data line segment is not provided with the support part PSZ, the first connecting part, and the second connecting part; the ninth data line segment is not provided with the support part PSZ, the first connecting part, and the second connecting part; and the tenth data line segment is not provided with the support part PSZ, the first connecting part, and the second connecting part.

Certainly, there may be other settings and arrangements, which will not be repeated here.

It should be noted that the support part PSZ provided in the embodiment of the present application is used to place a spacer PS. The spacer PS is set on the side of the support part PSZ away from the substrate to support the array base plate and the color film base plate, and improve the display performance of the display panel. In the embodiment of the present application, by setting the support part PSZ used to place the spacer PS on the data line DL, the design space can be greatly saved, which increases the opening rate of the display panel, thereby increasing the transparency of the display panel, improving the display effect, and reducing power consumption.

In the display panel provided in the embodiment of the present application, the display panel further includes spacers PS and protection parts PSB, the spacers PS are located at sides of part of the support parts PSZ away from the substrate, the protection parts PSB are located at at least one side of each of the support parts PSZ; and heights of the protection parts PSB in a direction perpendicular to a plane where the substrate is located is greater than heights of the support parts PSZ in the direction perpendicular to the plane where the substrate is located.

It should be noted that not all support parts PSZs require the spacers PS to be set.

Among them, the outer contour of the orthographic projection of the spacers PS on the substrate is located within the outer contour of the orthographic projection of the support parts PSZ on the substrate.

For example, in some embodiments, the support parts PSZ of a local region are provided with the spacers PS, and the support parts PSZ of another local region are not provided with the spacers PS.

For example, as shown in FIG. 29, no spacer PS is set on the support parts PSZ of the data line DL located at the junction of the first active area AA1 and the second active area AA2, but the spacer PS is set on the support parts PSZ of the data line DL in the first active area AA1.

Among them, the spacers PS include a main spacer MPS and an auxiliary spacer SPS.

There is no limitation on the quantity and distribution pattern of the main spacer MPS and the auxiliary spacer SPS here.

As an example, as shown in FIG. 29, in the local region of the data line DL, two connected data line segments are both provided with the support parts PSZ, the first connecting parts, and the second connecting parts. The two support parts PSZ are provided with one main spacer MPS and one auxiliary spacer SPS, respectively.

The design of the specific structure and size of the main spacer MPS and the auxiliary spacer SPS can refer to the instructions in related art, and which will not be repeated here.

In an exemplary embodiment, the protection parts PSB are set on both sides of each support part PSZ in the first active area AA1, and the protection part PSB is set on the side of each support part PSZ in the second active area AA2 close to the first active area AA1, the protection parts PSB are set in the sub pixel. When the spacers PS are offset or damaged, the protection parts PSB can protect the film structures in the sub-pixels from being scratched by the spacers PS, thus avoiding damage to the sub-pixels.

In exemplary embodiments, the thickness of the support parts PSZ is the same as that of the data line DL, and its thickness is determined based on the thickness of the source drain metal layer (SD layer).

In exemplary embodiments, the protection parts PSB include a first sublayer and a second sublayer, wherein the first sublayer is located in the gate layer (Gate layer) and the second sublayer is located in the source drain metal layer (SD layer). The thickness of the protection parts PSB is the sum of the thicknesses of the gate layer (Gate layer) and the source drain metal layer (SD layer).

In exemplary embodiments, the extension direction of the protection parts PSB is consistent with the extension direction of the sides of the support parts PSZ, in order to make the best possible use of space and reduce design difficulty.

In some embodiments, a protection part PSB can be set on both sides of the support part PSZ, and the protection layer PSB partially surrounds the support part PSZ.

In some embodiments, as shown in FIG. 29, two sets of protection parts PSB can be set on both sides of the support part PSZ. These two sets of protection parts PSB are symmetrically set, and one set of the protection parts PSB includes a larger size protection part PSB and a smaller size protection part PSB. The smaller size protection part PSB is located on the side of the larger size protection part PSB away from the support part PSZ.

In an exemplary embodiment, the graphics of the orthographic projection of the first conductive pattern of the first part 2/21 of the display panel on the substrate is a rectangle. As shown in FIG. 29, the upper half of the rectangle is provided with a plurality of vias Via, which are used to electrically connect the output end Gout of the GOA circuit in the peripheral area BB with the grid line GL in the active area AA, the lower half of the rectangle can be provided with a dummy transistor Dummy TFT or a first dummy capacitance Dummy C1.

In an exemplary embodiment, the peripheral area BB of the display panel also includes a common line BSL, one end of the common line BSL is electrically connected to the binding terminal of the display panel, and the other end is electrically connected to the common electrode line CML in the active area AA.

Among them, the common line BSL is also provided with a plurality of encoding patterns N0.1, which are used to mark the quantity of rows of the sub-pixels in the display panel.

Certainly, in other regions of the peripheral area BB, there are also a plurality of encoding patterns N0.2 used to mark the quantity of columns of the sub-pixels in the display panel.

The embodiment of the present application provides a display device, including a display panel as previously described.

The specific structure of the display panel can refer to the description in the previous text, and which will not be repeated here.

The display device can be a Liquid Crystal Display (LCD). For example, the LCD display device can include a Twisted Nematic (TN) type, a Vertical Alignment (VA) type, an In Plane Switching (IPS) type, and an Advanced Super Dimension Switch (ADS) type.

The display devices can be LCD displays and other display devices, as well as any products or components with display functions such as televisions, digital cameras, mobile phones, tablets, etc. that include these display devices.

In the display panel provided by the embodiment of the present application, by setting the projections of some first conductive patterns 2 overlap with the projections of the second conductive patterns 3, overlapping capacitors are formed, and the second conductive pattern 3 is electrically connected to the data line at the junction, thereby increasing the capacitive load of the data line at the junction and improving the load consistency between the data line at the junction and other data lines. While reducing the border size, the charging rate difference caused by RC signal delay difference is avoided, thereby avoiding the issue of uneven display brightness caused by the charging rate difference, and taking into account narrow borders and higher display effects. In addition, by setting that the first conductive patterns 2 and the second conductive pattern 3 are in the second active area AA2, and setting that the projections of some first conductive patterns 2 overlap with the projection of the second conductive pattern 3, the overlapping capacitance is formed, which can replace the Dummy sub-pixels in related art. As shown in FIG. 29, the size of the structure in the second active area AA2 is much smaller than the size of the sub-pixels, which may greatly reduce the border size of the display panel, and also ensure a good display effect.

The above are merely particular embodiments of the present application, and the protection scope of the present application is not limited thereto. All of the variations or substitutions that a person skilled in the art can easily envisage in the technical scope disclosed by the present application should fall in the protection scope of the present application. Therefore, the protection scope of the present application should be subject to the protection scope of the claims.

1. A display panel, comprising a first active area and at least one second active area, wherein the second active area is located at one side of the first active area, and the display panel further comprises;
a substrate;
a plurality of sub-pixels located on the substrate and arranged in array, wherein the plurality of sub-pixels are located in the first active area, and each of the plurality of sub-pixels comprises a common electrode;
a plurality of grid lines and a plurality of data lines that are located on the substrate, wherein the plurality of grid lines and the plurality of data lines are intersecting and insulated, the plurality of sub-pixels are located at a position defined by the plurality of grid lines and the plurality of data lines, at least one of the data lines is located at a junction of the first active area and the second active area;
a plurality of first conductive patterns, wherein the first conductive patterns are at least located in the second active area, and the first conductive patterns are electrically connected to one of the grid lines or the common electrode; and
a plurality of second conductive patterns located in the second active area and electrically connected to the at least one of the data lines located at the junction; wherein orthographic projections of part of the first conductive patterns on the substrate overlap with orthographic projections of the second conductive patterns on the substrate.

2. The display panel according to claim 1, wherein the plurality of first conductive patterns comprise a first part;
the first conductive patterns of the first part are located in the second active area and are electrically connected to the grid lines; and the orthographic projections of the second conductive patterns on the substrate are located within orthographic projections of the first conductive patterns of the first part on the substrate.

3. The display panel according to claim 1, wherein the plurality of first conductive patterns comprise a second part;
the first conductive patterns of the second part extend from the first active area to the second active area, and are electrically connected to the common electrode; orthographic projections of the first conductive patterns of the second part on the substrate overlap with an orthographic projection of the data line located at the junction on the substrate.

4. The display panel according to claim 2, wherein
outer contours of the orthographic projections of the second conductive patterns on the substrate are located within outer contours of the orthographic projections of the first conductive patterns of the first part on the substrate.

5. The display panel according to claim 4, wherein the second active area comprises a plurality of first dummy capacitances, the first conductive patterns of the first part are regarded as first electrodes of the first dummy capacitances, and the second conductive patterns are regarded as second electrodes of the first dummy capacitances.

6. The display panel according to claim 4, wherein the second active area comprises a plurality of dummy transistors, gates of the dummy transistors are electrically connected to the grid lines, first ends of the dummy transistors are electrically connected to the data line located at the junction, and second ends of the dummy transistors are arranged in isolation.

7. The display panel according to claim 6, wherein part regions of the first conductive patterns of the first part are regarded as the gates of the dummy transistors;
at least part of the second conductive patterns comprises first conductive parts and second conductive parts, the first conductive parts are disconnected from the second conductive parts, the first conductive parts are regarded as the first ends of the dummy transistors, and the second conductive parts are regarded as the second ends of the dummy transistors.

8. The display panel according to claim 7, wherein a quantity of the dummy transistors is less than or equal to half a quantity of rows of the sub-pixels.

9. The display panel according to claim 8, wherein each of the grid lines divides the data line located at the junction into a plurality of data line segments; the first active area comprises a plurality of transistors, part of the data line segments is electrically connected to the transistors, at least part of the data line segments that are not connected to the transistors is electrically connected to the dummy transistors.

10. The display panel according to claim 9, wherein the quantity of the dummy transistors is equal to half the quantity of rows of the sub-pixels, the data line segments that are not connected to the transistors are electrically connected to the dummy transistors, and the data line segments electrically connected to the transistors and the data line segments electrically connected to the dummy transistors are arranged at intervals.

11. (canceled)

12. The display panel according to claim 3, wherein the display panel comprises a plurality of second dummy capacitances, the first conductive patterns of the second part are regarded as first electrodes of the second dummy capacitances, part line segments of the data line located at the junction are regarded as second electrodes of the second dummy capacitances;
wherein an area of an orthographic projection of a part of the first conductive patterns of the second part that is located in the second active area on the substrate is greater than an area of an orthographic projection of a part of the first conductive patterns of the second part that is located in the first active area on the substrate.

13. The display panel according to claim 12, wherein graphics of the orthographic projections of the first conductive patterns of the second part on the substrate comprise polygons, arcs, or combinations of the polygons and the arcs.

14. The display panel according to claim 12, wherein graphics of the orthographic projections of the first conductive patterns of the second part on the substrate comprise a first side and a second side that face each other, extension directions of the first side and the second side are the same, the first side is located in the second active area, the second side is located in the first active area, a length of the first side along the extension direction of the first side is greater than or equal to a length of the second side along the extension direction of the second side.

15. The display panel according to claim 14, wherein in a direction perpendicular to a plane where the substrate is located, a distance from the first conductive patterns of the second part to the data line located at the junction is a first distance; and
the graphics of the orthographic projections of the first conductive patterns of the second part on the substrate comprise a right trapezoid, and a difference of sizes of an upper bottom and a lower bottom of the right trapezoid is proportional to the first distance.

16. The display panel according to claim 14, wherein in a direction perpendicular to a plane where the substrate is located, a distance from the first conductive patterns of the second part to the data line located at the junction is a first distance; and
the graphics of the orthographic projections of the first conductive patterns of the second part on the substrate comprise a combination of a rectangle and a first graphic, the first graphic comprises a plurality of right trapezoids, a right-angle side of each of the plurality of right trapezoids is in contact with the rectangle, and a sum of sizes of an upper bottom and a lower bottom of each of the plurality of right trapezoids is proportional to the first distance.

17. The display panel according to claim 12, wherein graphics of the orthographic projections of the first conductive patterns of the second part on the substrate comprise a combination of a second graphic and a third graphic that are connected, the second graphic comprises a chamfered rectangle, and the third graphic comprises a polygon, an arc, or a combination of the polygon and the arc;
wherein the second graphic extends from the first active area to the second active area, the third graphic is located in the second active area, a part of the first conductive patterns of the second part whose orthographic projection is the third graphic is in directly contact with a common electrode line of the display panel, and a chamfer of the chamfered rectangle is located in the second active area.

18. The display panel according to claim 12, wherein a quantity of the second dummy capacitance is greater than or equal to half a quantity of rows of the sub-pixels.

19. The display panel according to claim 18, wherein each of the grid lines divides the data line located at the junction into a plurality of data line segments; orthographic projections of at least part of the data line segments on the substrate overlap with the orthographic projections of the first conductive patterns of the second part on the substrate.

20-23. (canceled)

24. The display panel according to claim 2, wherein the display panel further comprises a third conductive pattern, the third conductive pattern is electrically connected to the common electrode, the third conductive pattern is at least located in the second active area, and at least part region of the third conductive pattern is located between the first conductive patterns of the first part and the data line located at the junction;
wherein an orthographic projection of the at least part region of the third conductive pattern on the substrate does not overlap with the orthographic projection of the data line located at the junction on the substrate.

25-29. (canceled)

30. A displaying device, comprising the display panel according to claim 1.
